(19) United States
(12) Patent Application Publication
(10) Pub. No.: US 2007/0224543 A1
(43) Pub. Date: Sep. 27, 2007

(54) Photopolymer Printing Plate Precursor

(75) Inventors: Willi-Kurt Griess, Mainz-Kastel (DE); Marc Van Damme, Bonheiden (BE)

Correspondence Address: AGFA;c/o KEATING & BENNETT, LLP, 8180 GREENSBORO DRIVE, SUITE 850, MCLEAN, VA, 22102, US

(73) Assignee: AGFA-GEVAERT, Mortsel (BE)

(21) Appl. No.: 11/568,742

(22) PCT Filed: Apr. 27, 2005
(86) PCT No.: PCT/EP05/51885

§ 371 Date: Nov. 6, 2006

Related U.S. Application Data
(60) Provisional application No. 60/577,674, filed on Jun. 7, 2004.

(30) Foreign Application Priority Data
May 6, 2004 (EP) 04101995.5

(51) Int. Cl. G03F 7/09

(52) U.S. Cl. 430/302; 430/496

(57) ABSTRACT

A photopolymer printing plate precursor includes, in this order, a photosensitive coating and ap pretective coating on a support, wherein te photosensitive coating includes a composition that is photopolymerizable upon absorption of light, the composition including a blidner, a polymerizable compound, a radical stabilizer, a sensitizer, and a photoinitiator. The photoinitiator is preferably a hexaaryl-bisimidazole compound and the protective layer has a dry coating weight from about 0.5 to less thatn about 2.0 g/m² and contains at least one type of poly(vinyl alcohol), having a saponification degree less than about 93 mol %, and a poly(vinyl pyrrolidone) in an amount from 0 to about 10 parts by weight of the poly(vinyl alcohol). The photopolymer printing plate is very stable at high pre-heat temperatures.

### BACKGROUND OF THE INVENTION

1. Field of the Invention

The present invention relates to a photopolymer printing plate precursor including, in this order, a support, a photosensitive coating, and a protective coating, wherein the photosensitive coating includes a composition that is photopolymerizable upon absorption of light, the composition including a binder, a polymerizable compound, a radical stabilizer, a sensitizer, and a photoinitiator.

The invention also relates to a method of making a lithographic printing plate therewith.

2. Description of the Related Art

In lithographic printing, a so-called printing master such as a printing plate is mounted on a cylinder of the printing press. The master carries a lithographic image on its surface and a printed copy is obtained by applying ink to the image and then transferring the ink from the master onto a receiver material, which is typically paper. In conventional, so-called “wet” lithographic printing, ink as well as an aqueous fountain solution (also called dampening liquid) are supplied to the lithographic image which consists of oleophilic (or hydrophobic, i.e., ink-accepting, water-repelling) areas as well as hydrophilic (or oleophobic, i.e., water-accepting, ink-repelling) areas. In so-called “driographic” printing, the lithographic image consists of ink-accepting and ink-abhesive (ink-repelling) areas and during driographic printing, only ink is supplied to the master.

Printing masters are generally obtained by the so-called computer-to-film (CtF) method, wherein various pre-press steps such as typeface selection, scanning, color separation, screening, trapping, layout, and imposition are accomplished digitally and each color selection is transferred to graphic arts film using an image-setter. After processing, the film can be used as a mask for the exposure of an imaging material called a plate precursor and after plate processing, a printing plate is obtained which can be used as a master. Since about 1995, the so-called ‘computer-to-plate’ (CtP) method has gained a lot of interest. This method, also called ‘direct-to-plate’, bypasses the creation of film because the digital document is transferred directly to a printing plate precursor by means of a so-called plate-setter. A printing plate precursor for CtP is often called a digital plate.

Digital plates can roughly be divided into three categories: (i) silver plates, which work according to the silver salt diffusion transfer mechanism; (ii) photopolymer plates which contain a photopolymerizable composition that hardens upon exposure to light, and (iii) thermal plates of which the imaging mechanism is triggered by heat or by light-to-heat conversion. Thermal plates are mainly sensitized for infrared lasers emitting at 830 nm or 1064 nm. Typical photopolymer plates are sensitized for visible light, mainly for exposure by an Ar laser (488 nm) or a FD-YAG laser (532 nm). The wide-scale availability of low cost blue or violet laser diodes, originally developed for data storage by means of DVD, has enabled the production of plate-setters operating at shorter wavelength. More specifically, semiconductor lasers emitting from 350 to 450 nm have been achieved using an InGaN material.

Radicals are involved in the hardening reaction of the photopolymerizable composition of photopolymer plates and the hardening reaction is known to be adversely affected by oxygen. To reduce this problem it is known to provide the photosensitive coating with a protective coating, also called an oxygen barrier layer, protective overcoat, or overcoat layer.

According to DE 26 29 883 A1, the oxygen barrier layer of a presensitized lithographic printing plate should contain a poly(vinyl alcohol), wherein at least 2% of the hydroxy groups of the poly(vinyl alcohol) are esterified by a dicarboxylic acid, to provide an oxygen barrier layer, that can be dissolved in the same solvent as used for the developer and that does not adversely affect the image forming process. The printing plate precursors known from DE 26 29 883 only have a low sensitivity, what is disclosed on p. 17, reading that low exposure (corresponding to high sensitivity) means 3 s when using four high pressure mercury vapour lamps of 150 Watts each.

EP 1 148 387 A1 discloses photographic printing plates including a photosensitive layer and a protective layer, that have a maximum peak of spectral sensitivity with a wavelength range of from 390 to 430 nm, and wherein the minimum exposure for the photosensitive lithographic printing plate for image formation at a wavelength of 410 nm is at most 100 μJ/cm². The protective layer is provided on the photosensitive layer as an oxygen-shielding layer and preferred examples of protective layers according to EP 1 148 387 A1 contain water-soluble polymers such as poly(vinyl alcohol), poly(vinyl pyrrolidone), poly(ethylene oxide) and cellulose; a mixture of poly(vinyl alcohol) and poly(vinyl pyrrolidone) being particularly preferred.

According to EP 1 280 006 A2, a protective layer is provided on the layer of photopolymerizable composition, wherein the protective layer inhibits the penetration of a low molecular compound such as oxygen and can contain water-soluble polymers that have relatively high crystallinity. Preferably, poly(vinyl alcohol) with a saponification degree of 71% to 100% is used as a basic component, that may be partially replaced by an ester, ether, or acetal; and the photopolymerizable composition includes a photopolymerization initiation system consisting of a specific sensitizing dye and a titanocene compound.

To improve the behaviour of photopolymerization compositions prior to exposure, that is, to reduce unwanted polymerization during preparation and storage of photopolymerizable compositions it is known from, e.g., EP 0 924 570 A1, EP 1 035 435 A2, EP 1 070 990 A1 and EP 1 081 552 A1 to add thermopolymerization inhibitors to the photosensitive compositions.

EP 0 738 929 discloses a photopolymerizable sensitive material which includes a support, a photopolymerizable sensitive layer including an addition polymerizable compound, a photopolymerizable initiator and a binder, formed on a support, and a protective layer formed thereon, that includes a mixture of (a) polyvinylalcohol and/or a polyvinylalcohol derivative (PVA) and (b) a polyvinyl pyrrolidone (PVP), whereby the proportion of component (a) in the total amount of components (a) and (b) is from 25 to 75 weight %.

EP 1 288 722 discloses a printing plate precursor, wherein the photopolymerizable layer includes a titanocene type initiator.

After imaging (exposing) the photopolymer printing plate precursor, the plate is heated for a short time to a high temperature before the overcoat is washed off and the photolayer is developed. This heating step is hereinafter called a pre-heat step. During the pre-heat step, typical temperatures, when measured at the back of the plate, from about 90° C. to 150° C. are used for a short time, typically between 10 seconds and 1 minute. As the conditions of the pre-heat step vary with different types of processors and even for the same processor, a printing plate should exhibit consistent results irrespective of the pre-heat conditions, in particular to the temperature. The range of pre-heat conditions, wherein a printing plate exhibits consistent results is called the pre-heat latitude of the plate.

In particular when using high pre-heat temperatures, so called ‘asteroid’ defects often occur in non-image areas of known printing plates. Such asteroids are of irregular shape having a mean diameter of about 1 to 50 μm. As such asteroids adsorb ink and therefore print the ink, although being in an unexposed area, they deteriorate the quality of the resulting print and are prohibitive for high quality results. The maximum pre-heat temperature that can be used for a given printing plate precursor without the occurence of asteroid defects is called Tₘₐₓ(‘asteroid’-free).

The photopolymer printing plate precursors according to the prior art are unsatisfactory, as such plates exhibit an unsatisfactory Tₘₐₓ(‘asteroid’-free), in particular when providing sufficient speed (sensitivity) to enable a short exposure time with the commercially available low cost and low power blue or violet laser diodes.

### SUMMARY OF THE INVENTION

In order to overcome the problems described above, preferred embodiments of the present invention provide a high-speed photopolymer printing plate precursor, that has a high Tₘₐₓ(‘asteroid’-free) and therefore is suitable for all known types of processors and processes used to make a printing plate. The printing plate precursor may a flexographic or lithographic printing plate precursor, the latter being preferred. Another preferred embodiment of the present invention is a method of making a lithographic printing plate, wherein the printing plate precursor is exposed with a laser having an emission wavelength in the range from about 300 to about 450 nm. Preferred photopolymer printing plate precursors can be exposed with an energy density, measured on the surface of the plate of about 100 μJ/cm² or less. Further preferred embodiments of the printing plate precursor, the method of making a lithographic printing plate, and the use of the printing plate precursor are also disclosed.

### DETAILED DESCRIPTION OF PREFERRED EMBODIMENTS

The present preferred embodiment relates to a photopolymer printing plate precursor including, in this order, a support, a photosensitive coating, and a protective coating, wherein the photosensitive coating includes a composition that is photopolymerizable upon absorption of light, the composition including a binder, a polymerizable compound, a radical stabilizer, a sensitizer, and a photoinitiator, wherein the photoinitiator is a hexaaryl-bisimidazole compound and the protective layer has a dry coating weight from about 0.5 g/m² to less than about 2.0 g/m², preferrably from about 0.50 g/m² to about 1.90 g/m², and contains at least one type of poly(vinyl alcohol), having a saponification degree less than about 93 mol %, and a poly(vinyl pyrrolidone) in an amount from 0 to about 10 parts by weight of the poly(vinyl alcohol).

By adjusting the dry coating weight of the protective layer of a photopolymer printing plate precursor to an amount smaller than about 2.0 g/m², a substantially higher Tₘₐₓ(‘asteroid’-free) can be achieved, if the photopolymerizable composition covered by the protective layer includes a radical stabilizer.

According to the present preferred embodiment, the photoinitiator is a hexaaryl-bisimidazole compound. Using the photoinitiator results in a higher Tₘₐₓ(‘asteroid’-free) and in a higher sensitivity compared to known printing plate precursors.

According to the present preferred embodiment, the saponification degree of the polyvinylalcohol is less than about 93 mol-% and a polyvinylpyrrolidone is used in an amount from 0 to about 10 parts by weight of the polyvinylalcohol. In a preferred embodiment, a mixture of at least two types of polyvinylalcohol are used having an overall mean saponification degree of all the polyvinylalcohols which are used in the protective coating of less than about 93 mol-% and a polyvinylpyrrolidone is used in an amount from 0 to about 10 parts by weight of the polyvinylalcohols. Thereby a printing plate precursor is achieved having a higher Tₘₐₓ(‘asteroid’-free), the dot gain of which depends less on the pre-heat temperature.

The radical stabilizer can be selected from known radical stabilizers. Compounds useful as radical stabilizers are also known as antioxidants or radical scavengers that are used as additives for, e.g., polymers. Preferably, the radical stabilizer used in the present preferred embodiment is a compound selected from the group consisting of phenoles, organic phosphites, organic phosphonites, amines, hydroxylamines, lactones, hydrochinones, divalent sulfur compounds like thioethers and thioesters, metal complexants, wherein phenoles include mono-, di- and trihydroxyphenyl compounds, and in particular the radical stabilizer used in the present preferred embodiment is a compound selected from the group consisting of hindered phenoles, O-alkylated hydrochinones, organic phosphites, organic phosphonites, aromatic amines, hindered amines, dialkyl hydroxylamines, benzofuranones and dialkyl thiodipropionates. The members of the groups are also called classes in the following.

Hindered phenoles that are particularly preferred for the present preferred embodiment are substituted by at least one tertiary butyl group neighbouring to the phenolic hydroxy group. Further advantages can be achieved with phenolic compounds that contain long chain alkyl or alkylene groups, in particular such groups having from 6 to 25 C-atoms, from 9 to 22 C-atoms being further preferred. The phenolic compounds can include one, two, three or more phenol rings (mono-, di-, tri- or poly-phenolic compounds), one to six phenol rings being preferred. Tocopherols (see, e.g., stabilizer (ST-20) in the following) are also useful radical stabilizers according to the present preferred embodiment.

The organic phospites and phosphonites preferably are esters of hindered phenols as defined above and/or esters of long chain alkoxy groups, wherein long chain has the same meaning as defined above.

Aromatic amines used as stabilizers according to the present preferred embodiment preferably are N,N′-disubstituted p-phenylenediamines, substituted diphenylamines or substituted dihydrochinolines, wherein optionally substituted phenyl groups and/or alkyl groups are preferred as substituents.

Hindered amines, known as light stabilizers, are also useful radical stabilizers of the present preferred embodiment. Preferred hindered amines are derivatives of 2,2,6,6-tetramethylpiperidine (see e.g. (ST-28) in the following).

A radical stabilizer according to the present preferred embodiment can belong to only one of the classes listed above, but can also belong to two, three, or a plurality of those classes. For example, the stabilizer of formula (ST-13) (see below) belongs to the classes hindered phenoles and thioethers.

Some radical stabilizers, when incorporated in the photopolymerizable composition according to the preferred embodiments of the present invention, improve the Tₘₐₓ(‘asteroid’-free) even if the protective layer has a dry coating weight of about 2.0 g/m² or more, in particular up to about 5.0 g/m². Such stabilizers are called hereinafter particular efficient stabilizers. Nevertheless even when using the particular efficient stabilizers, the Tₘₐₓ(‘asteroid’-free) is substantially improved, if the protective layer has a dry coating weight of about 0.5 to less than about 2.0 g/m².

In a particularly preferred embodiment of the present invention, the radical stabilizer is selected from the group of particular efficient stabilizers, this group consisting of phenolic compounds with more than two phenolic groups, organic phosphites, organic phosphonites, and hindered amines.

In a further preferred embodiment of the present invention the group of particular efficient stabilizers consists of hindered tri- and tetra-phenoles, hindered phenol esters of organic phosphites, and hindered phenol esters of organic phosphonites.

The photosensitive coating according to the present preferred embodiment can include one, two, three, or more different radical stabilizers. In the case where it contains more than one radical stabilizer, the compounds can belong to the same or different classes.

Preferred examples of radical stabilizers according to the present preferred embodiment are given in the following.

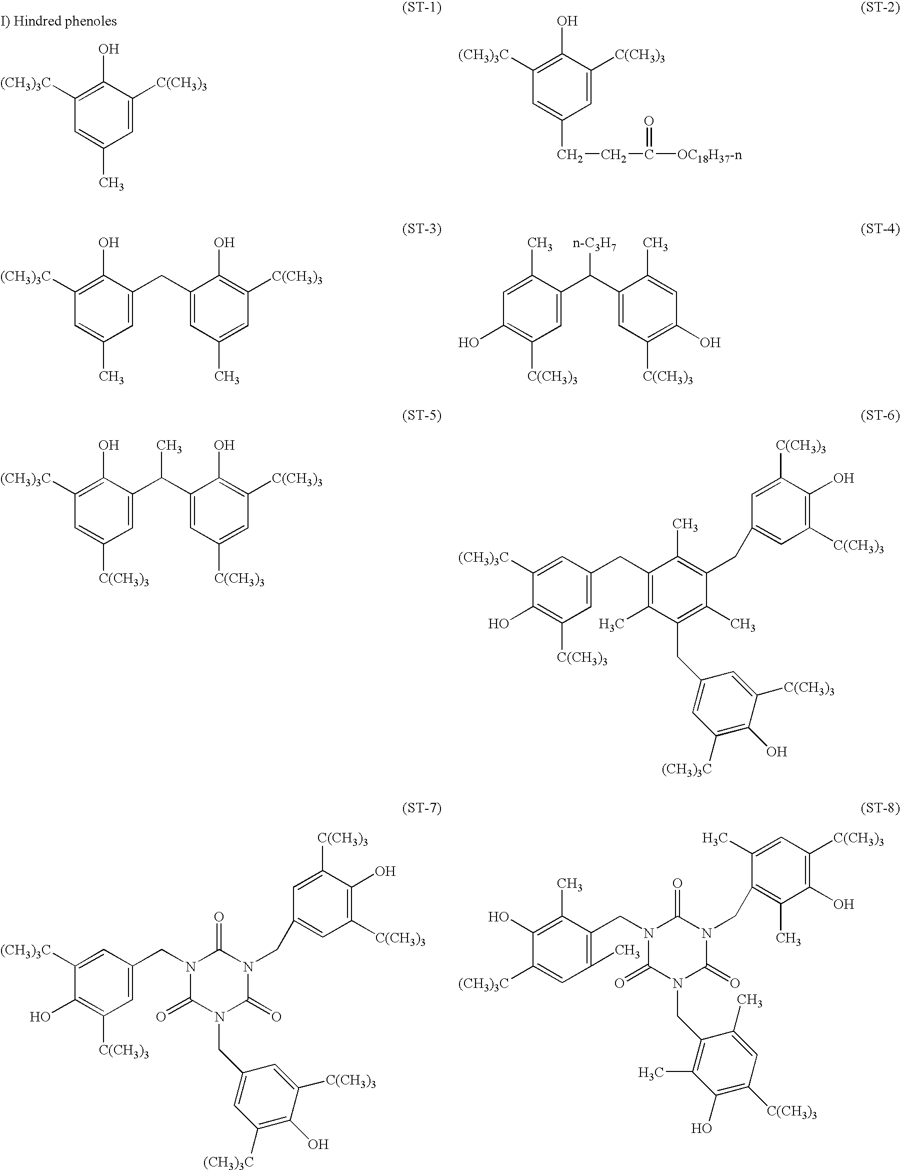

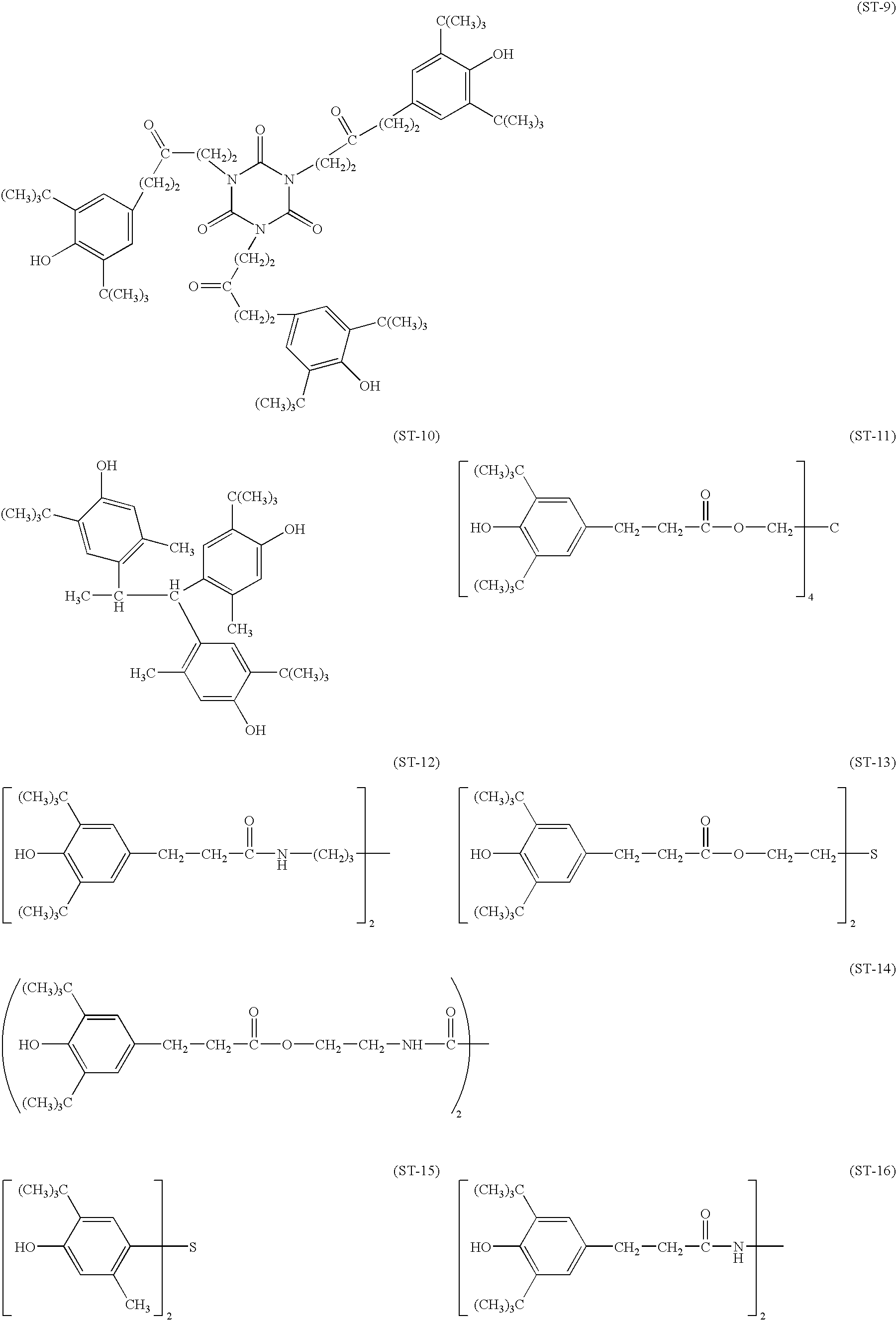

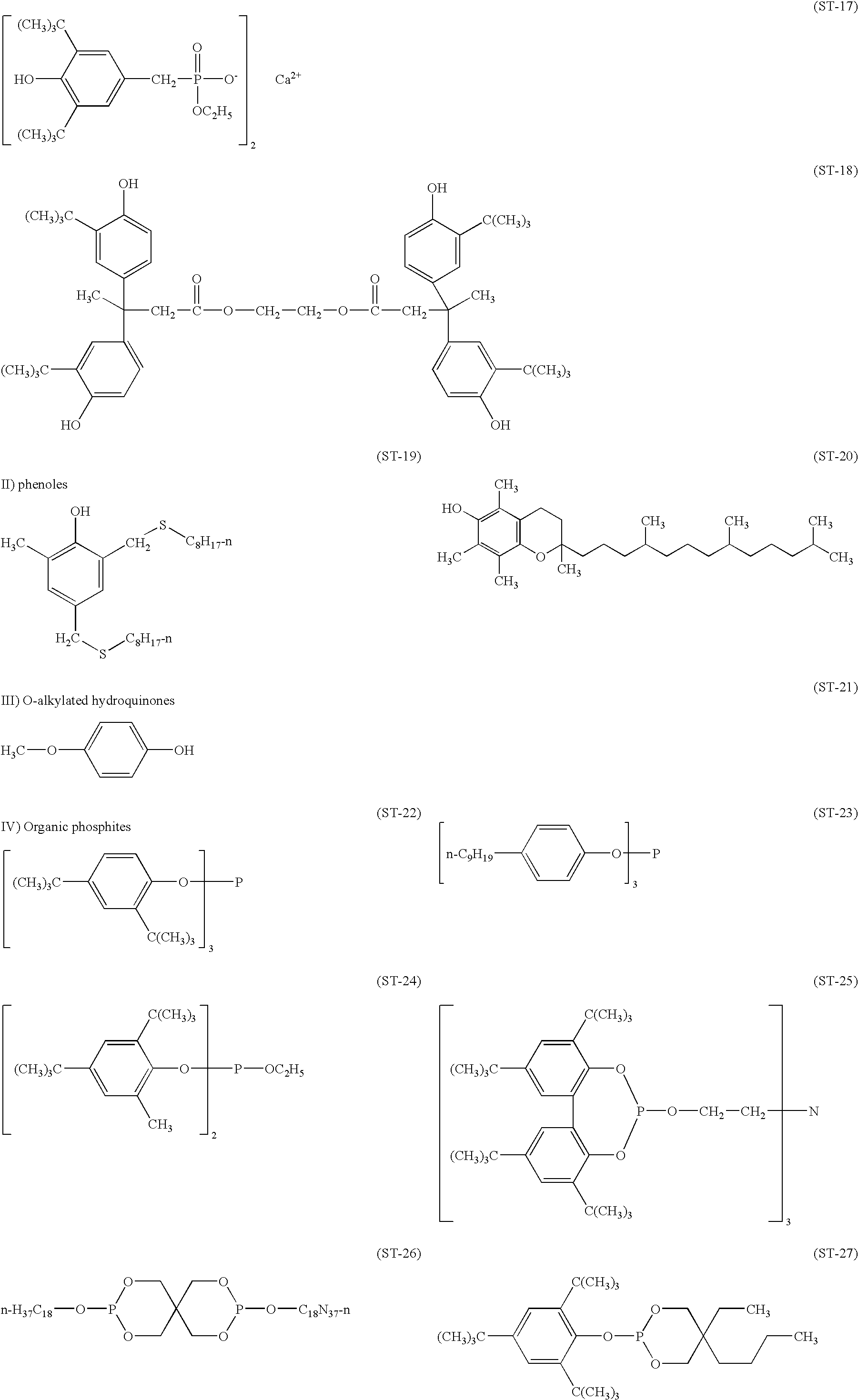

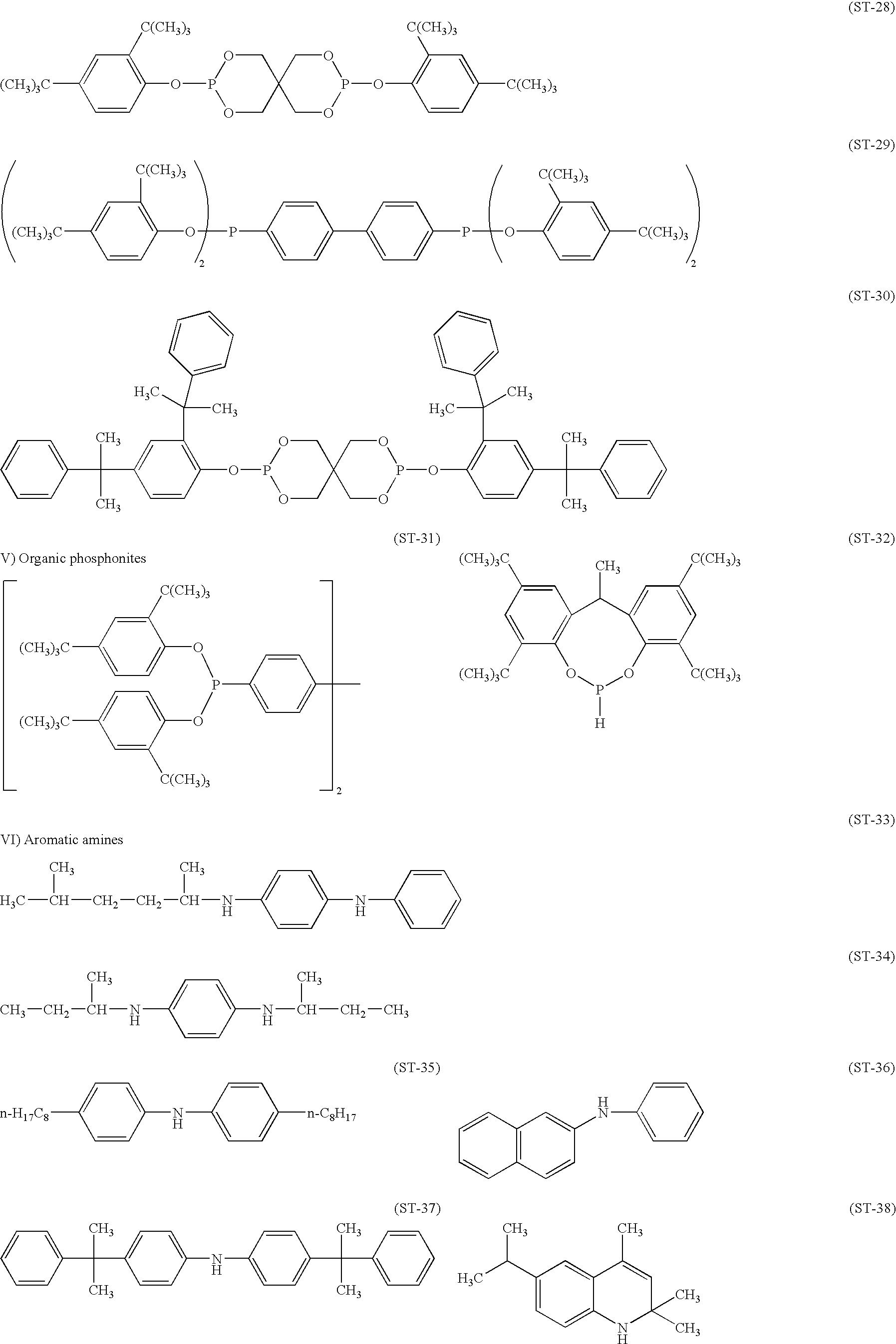

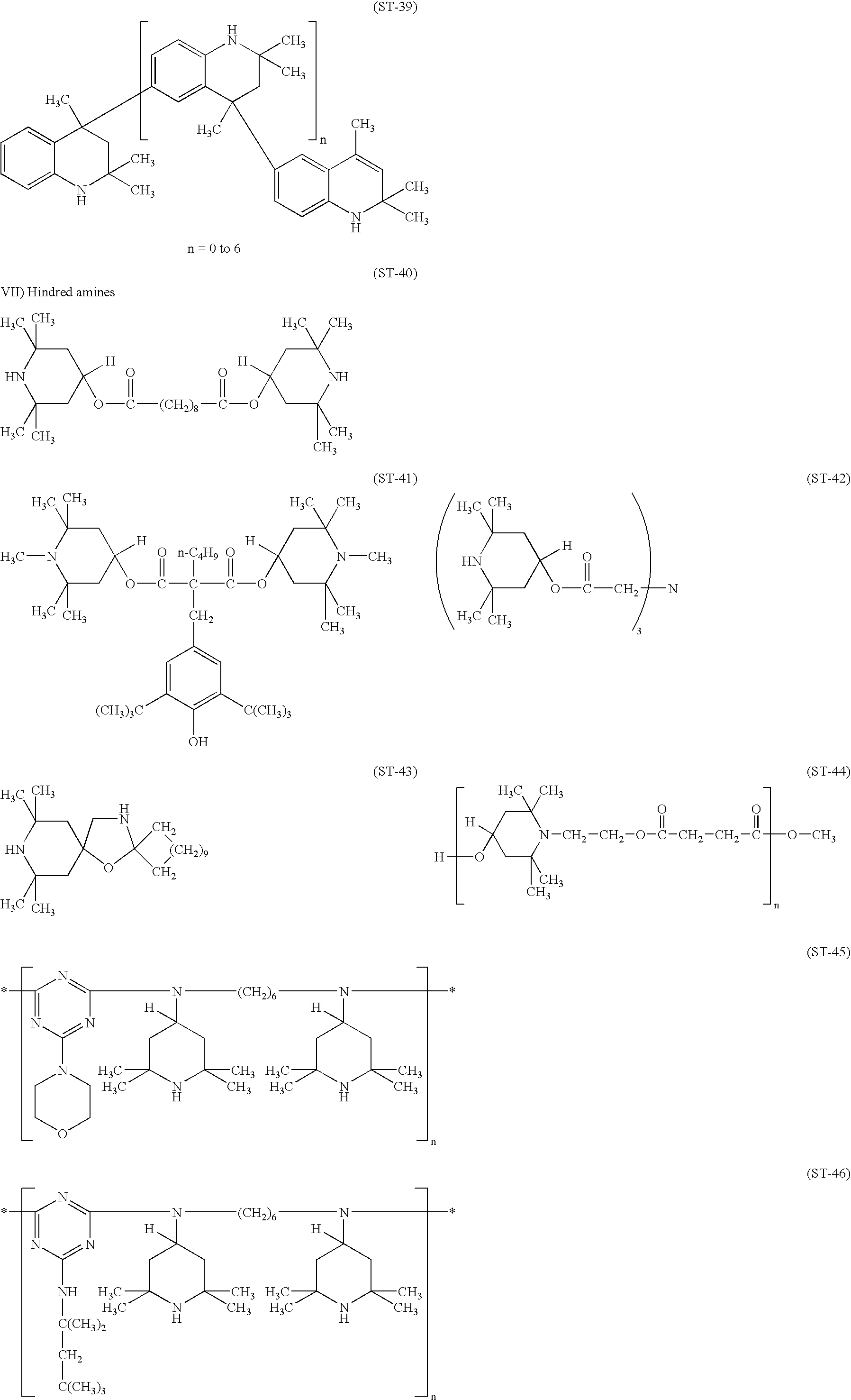

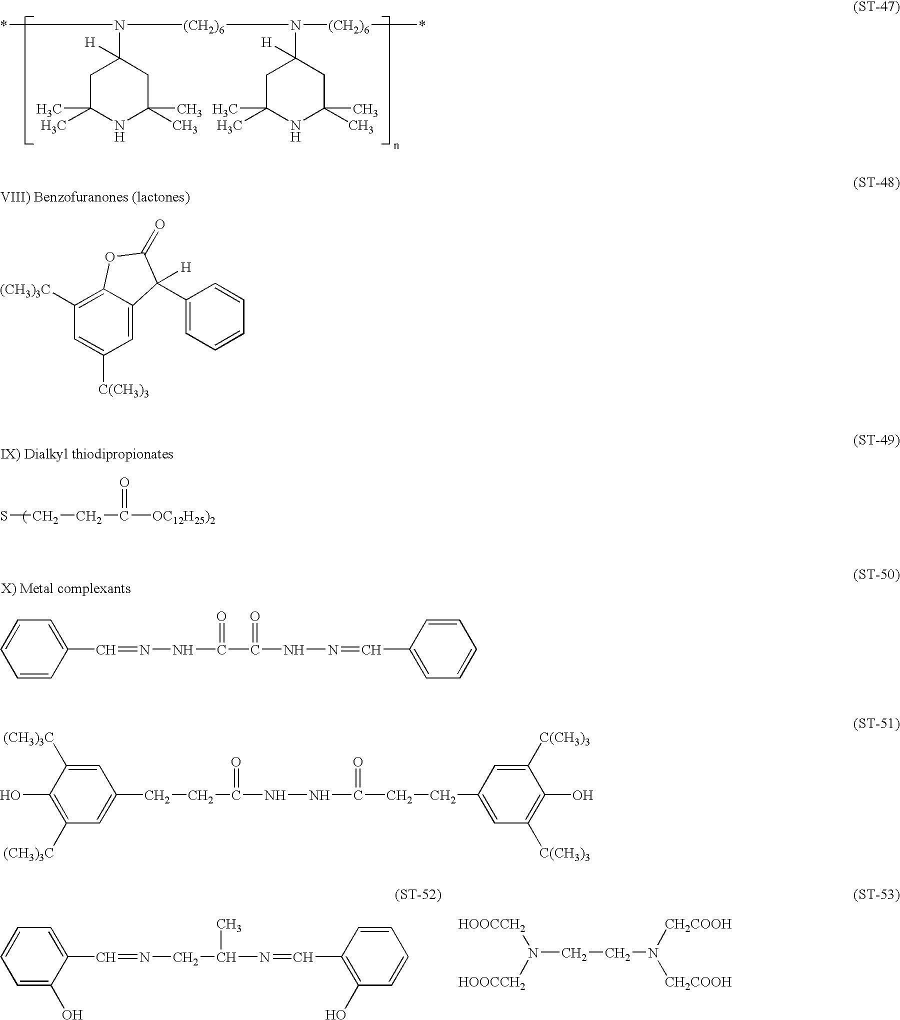

Further examples of radical stabilizers are butylated hydroxyanisole, 3-tert-butyl-4-methoxyphenol, n-propyl gallate (3,4,5-trihydroxybenzoic acid propyl ester), pyrogallol (1,2,3-trihydroxybenzene), t-butyl catechol (t-butyl brenzcatechine), benzochinone, citric acid, N-nitrosophenylhydroxylamine, and salts thereof.

The radical stabilizers according to the present preferred embodiment are preferably incorporated in the photopolymerizable composition in an amount of about 0.01 to about 5 wt. %, in particular from about 0.015 to about 3 wt. %, with respect to the total weight of the non-volatile compounds of the photopolymerizable composition.

A sensitizing dye (sensitizer) preferably used in the present preferred embodiment, when incorporated in the photopolymerizable composition, has an absorption wavelength ranging from about 300 to about 450 nm, preferably from about 350 to about 430 nm and particularly preferred from about 360 to about 420 nm, and makes the photopolymer printing plate sensitive to light within the wavelength ranges.

In a preferred embodiment of the present invention, a sensitizer having a solubility in methyl ethyl ketone of at least 15 g/kg, preferably from about 15 to about 250 g/kg, measured at 20° C. is used. Using such highly soluble sensitizers results in a higher Tₘₐₓ(‘asteroid’-free) and in a material having less pinhole defects. Defects called pinholes are areas having lateral dimensions of about 50 to about 500 μm on the processed printing plate, that don't take up ink and therefore result in exposed areas that do not print. This unfavourable effect is particularly noticeable if the printing plate precursor is stored before exposure and processing thereof.

Known sensitizing dyes can be used in the composition of the preferred embodiments of the present invention. Suitable classes include dialkylaminobenzene compounds like (Ia) and (Ib):

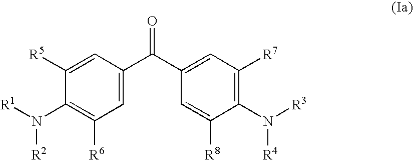

wherein each of R¹ to R⁴, which are independent of one another, is an alkyl group having 1 to 6 carbon atoms (C₁₋₆ alkyl group), and each of R⁵ to R⁸ is a hydrogen atom or a C₁₋₆ alkyl group, provided that R¹ and R², R³ and R⁴, R¹ and R⁵, R² and R⁶, R³ and R⁷, or R⁴ and R⁸, may be bonded to each other to form a ring;

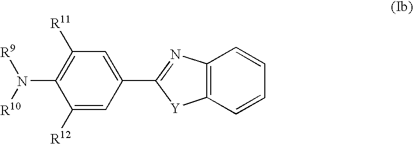

wherein each of R⁹ and R¹⁰, which are independent of each other, is a C₁₋₆ alkyl group, each of R¹¹ and R¹², which are independent of each other, is a hydrogen atom or a C₁₋₆ alkyl group, Y is a sulfur atom, an oxygen atom, dialkylmethylene or —N(R¹³)—, and R¹³ is a hydrogen atom or a C₁₋₆ alkyl group, provided that R⁹ and R¹⁰, R⁹ and R¹¹, or R¹⁰ and R¹², may be bonded to each other to form a ring, as disclosed in EP 1 148 387 A1; compounds according to formula (II)

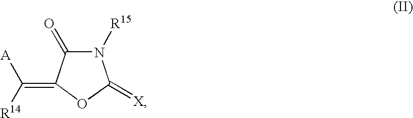

wherein A represents an optionally substituted aromatic ring or heterocyclclic ring, X represents an oxygen atom, a sulfur atom or —N(R¹⁶)—, R¹⁴, R¹⁵ and R¹⁶ each independently represent a hydrogen atom or a monovalent nonmetallic atom group and A and R¹⁴, or R¹⁵ and R¹⁶ can be linked together to form an aliphatic or an aromatic ring, as disclosed in EP 1 280 006 A2; 1,3-dihydro-1-oxo-2H-indene compounds as disclosed in EP 1 035 435 A2; the sensitizing dyes disclosed in EP 1 048 982 A1, EP 985 683 A1, EP 1 070 990 A1 and EP 1 091 247 A2; and/or an optical brightening agent.

To achieve a very high sensitivity, an optical brightening agent as a sensitizer is preferred. A typical optical brightener, also known as a “fluorescent whitening agent,” is a colorless to weakly colored organic compound that is capable of absorbing light having a wavelength in the range from about 300 to about 450 nm and of emitting the absorbed energy as fluorescent light having a wavelength in the range between about 400 and about 500 nm. A description of the physical principle and the chemistry of optical brighteners is given in Ullmann's Encyclopedia of Industrial Chemistry, Sixth Edition, Electronic Release, Wiley-VCH 1998. Basically, suitable optical brighteners contain π-electron systems including a carbocyclic or a heterocyclic nucleus. Suitable representatives of these compounds are, e.g., stilbenes, distyrylbenzenes, distyrylbiphenyls, divinylstilbenes, triazinylaminostilbenes, stilbenyltriazoles, stilbenylnaphthotriazoles, bis-triazolstilbenes, benzoxazoles, bisphenylbenzoxazoles, stilbenylbenzoxazoles, bis-benzoxazoles, furans, benzofurans, bis-benzimidazoles, diphenylpyrazolines, diphenyloxadiazoles, coumarins, naphthalimides, xanthenes, carbostyrils, pyrenes, and 1,3,5-triazinyl-derivatives.

More specifically, optical brightening agents having a structure according to one of the following formulae are suitable as a sensitizer for use in the composition of the preferred embodiments of the present invention: 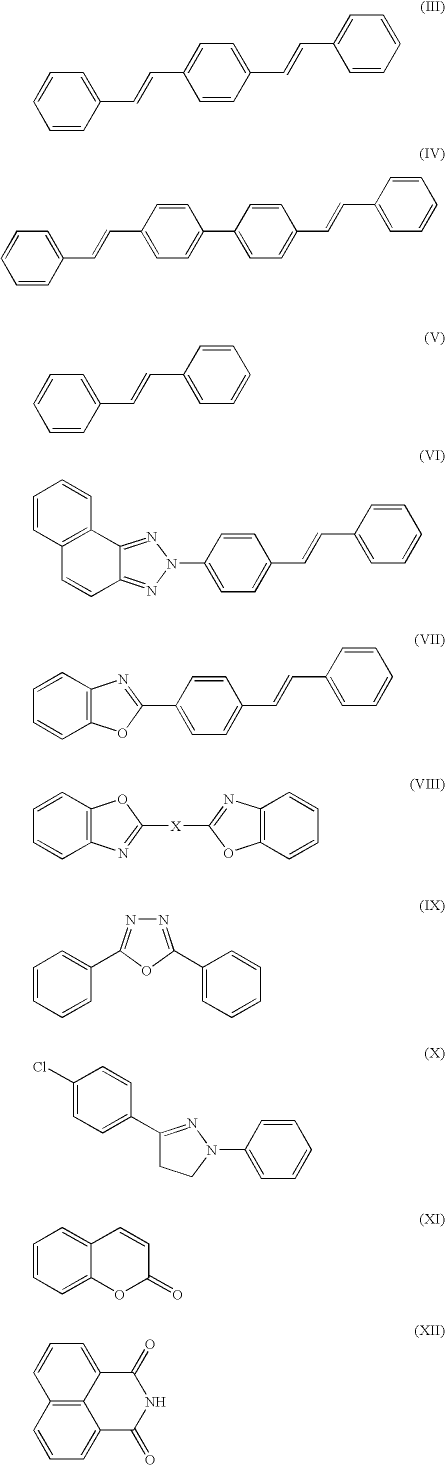 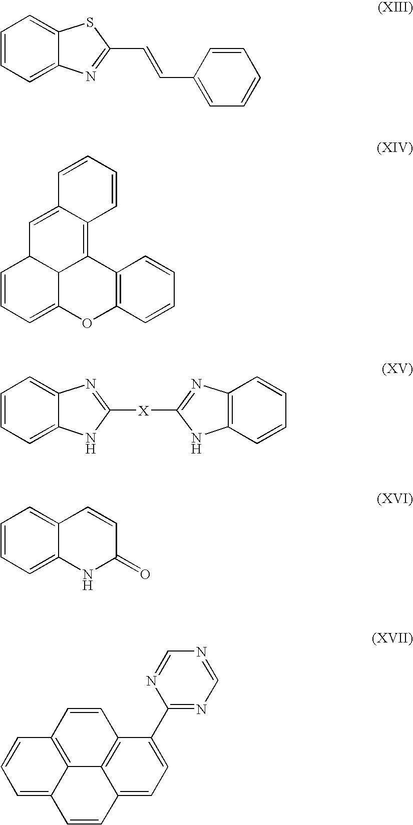
wherein X is one of the following groups, * denoting the position of attachment in the above formulae: 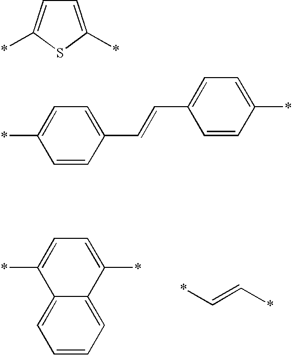
and wherein one or more of the nuclei in each of the above formulae (III) to (XVII) may be independently substituted by one or more groups selected from alkyl, alkoxy, alkylcarbonyl, alkoxycarbonyl, acyloxy, carboxyl, nitrile, amino, hydroxyl, alkylsulfonyl, and aminosulfonyl.

Especially suitable optical brighteners are compounds, which are able to be dissolved in organic solvents. The optical brighteners can be used as a single compound or as mixture of several materials. The overall amount of these compounds range from about 0.1 to about 10% by weight, preferably about 0.5 to about 8% by weight with respect to the total weight of the non-volatile compounds in the photopolymerizable composition.

Highly preferred optical brighteners include compounds of formula (III-A) to (VIII-A): 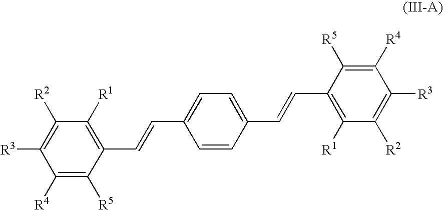
wherein
a) R¹ represents methyl, and R² to R⁵ each represent H,
b) R² to R⁴ represent methoxy, and R¹ and R⁵ represent H,
c) R¹ represents CN, and R² to R⁵ each represent H, or
d) R³ represents CN, and R¹, R², R⁴ and R⁵ each represent H; 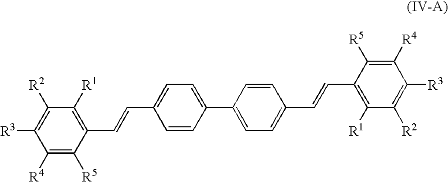
   wherein R¹ to R⁴ each represent H, and R⁵ represents methoxy; 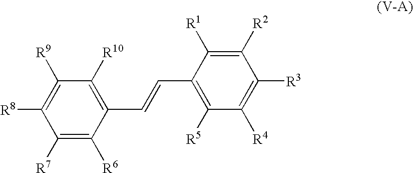
   wherein
a) R¹ to R¹⁰ each represent H,
b) R¹, R² and R⁴ to R¹⁰ each represent H, and R³ represents methoxy, or
c) R¹, R², R⁴ to R⁷, R⁹ and R¹⁰ each represent H, and R³ and R⁸ each represent methoxy; 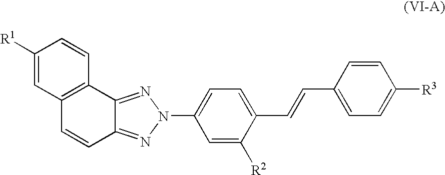
   wherein
a) R¹ and R³ represent H, and R² represents phenylsulfonic acid or phenylsulfonic acid salts, or
b) R¹ represents H, R² represents CN and R³ represents Cl; 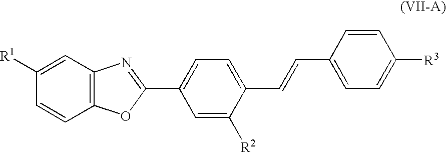
   wherein
a) R¹ represents t-butyl, R² represents H and R³ represents phenyl,
b) R¹ represents methyl, R² represents H, and R³ represents carboxymethyl, or
c) R¹ represents H, R² represents H, and R³ represents 2-(4-methyl-oxa-3,3-diazole); 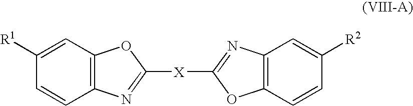
   wherein
a) X represents 4,4′-stilbenediyl, and R¹ and R² each represent H,
b) X represents 2,5-thiophenediyl, and R¹ and R² each represent t-butyl,
c) X represents 1,4-naphthalenediyl, and R¹ and R² each represent H, or
d) X represents 1,1-ethenediyl, and R¹ and R² each represent methyl; 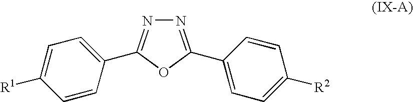
   wherein R¹ and R² each represent diethylamino; 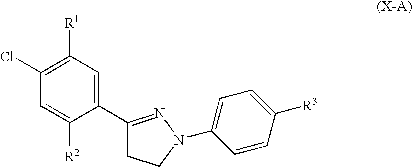
   wherein
a) R¹ and R² each represent H, and R³ represents SO₂NH₂,
b) R¹ and R² each represent H, and R³ represents SO₂CH₂CH₂OCH₂CH₂N(CH₃) 2,
c) R¹ and R² each represent H, and R³ represents SO₂CH₂CH₂OCH(CH₃)CH₂N(CH₃)_{2,}
d) R¹ and R² each represent H, and R³ represents SO₂CH₃, or
e) R¹ and R² each represent H, and R³ represents SO₂CH₂CH₂OH; 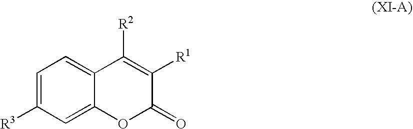
   wherein
a) R¹ represents H, R² represents Me, and R³ represents diethylamino,
b) R¹ represents phenyl, R² represents H, and R³ represents 2-N-naphthatriazolyl,
c) R¹ represents H, R² represents methyl, and R³ represents OH,
d) R¹ represents phenyl, R² represents H, and R³ represents NH-(4,6-dichloro)-(1,3,5)-triazine, or
e) R¹ represents Ph, R² represents H, and R³ represents 1-(3-methylpyrazolinyl); 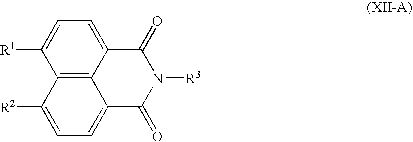
   wherein
a) R¹ represents H, R² represents methoxy, and R³ represents methyl; or
b) R¹ and R² each represent OEt, and R³ represents methyl; 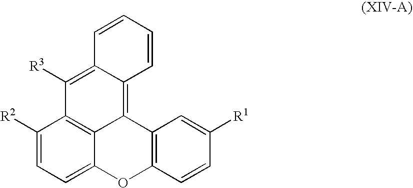
   wherein
a) R¹ and R² each represent methyl, and R³ represents H, or
b) R¹ and R² each represent methyl, and R³ represents carboxymethyl; 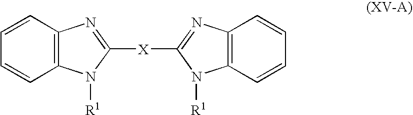
   wherein
a) X represents 1,2-ethenediyl, and R¹ represents Me, or
b) X represents 4,4′-stilbenediyl, and R¹ represents methyl; 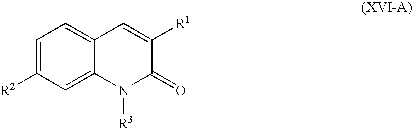
   wherein R¹ represents Ph, R² represents diethylamino, and R³ represents ethyl; and 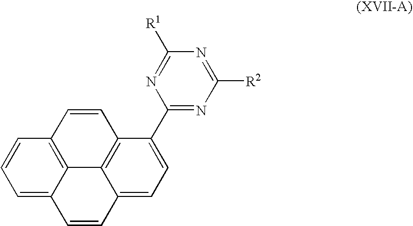
   wherein R¹ and R² each represent methoxy.

From those sensitizers, the following compounds of formulae (IIIa) and/or (IVa) are particularly preferred: 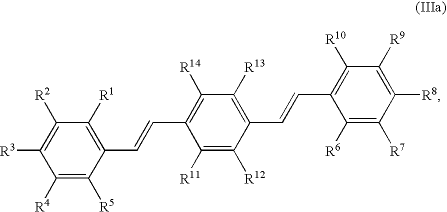
wherein
R¹ to R¹⁴ in dependently represent a hydrogen atom, an alkyl group, an alkoxy group, a cyano group, or a halogen atom, and at least one of R¹ to R¹⁰ represents an alkoxy group having more than 1 carbon atom; 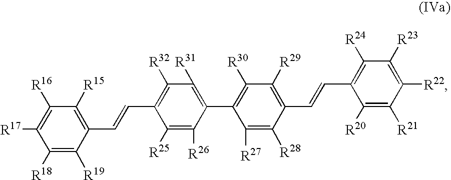
   wherein
R¹⁵ to R² independently represent a hydrogen atom, an alkyl group, an alkoxy group, a cyano group, or a halogen atom, and at least one of R¹⁵ to R²⁴ represents an alkoxy group having more than 1 carbon atom. The alkyl and alkoxy groups of the present preferred embodiment can be optionally substituted and their substituent can be selected to adjust the solubility of the sensitizer and may be, for example, halogen, ester, ether, thioether or hydroxy. The alkyl or alkoxy groups may be straight chain or cyclic, but a branched chain is preferred for the sensitizers of formulae (IIIa) and (IVa).

Particular advantages are achieved with sensitizers of formula (IIIa), wherein R¹, R⁵, R⁶, R¹⁰, R¹¹, R¹², R¹³ and R¹⁴ independently represent a hydrogen atom, a fluorine atom, or a chlorine atom, in particular R¹, R⁵, R⁶, and R¹⁰ being a hydrogen atom; R² to R⁴, R⁷ to R⁹, independently are alkoxy groups; and at least two of the alkoxy groups are branched and have from 3 to 15 carbon atoms. Especially preferred are sensitizers of formulae (IIIa) as disclosed above, wherein R², R⁴, R⁷, R⁹ independently represent a methoxy group and R³ and R⁸ independently are branched alkoxy groups having 3 to 15 carbon atoms.

Particular advantages are also achieved with sensitizers of formula (IVa), wherein R¹⁵, R¹⁹, R²⁰, R²⁴, R²⁵ to R³², independently represent a hydrogen atom, a fluorine atom, or a chlorine atom, in particular R¹⁵, R¹⁹, R²⁰, R²⁴ being a hydrogen atom; R¹⁶ to R¹⁸, R²¹ to R²³, independently are alkoxy groups; and at least two of the alkoxy groups are branched and have from 3 to 15 carbon atoms. Especially preferred are sensitizers of formulae (IVa) as disclosed above, wherein R¹⁶, R¹⁸, R²¹, R²³ independently represent a methoxy group and R¹⁷ and R²² independently are branched alkoxy groups having 3 to 15 carbon atoms.

The following structures are examples of preferred sensitizers and their solubility S is given in brackets as g sensitizer/kg methyl ethyl ketone measured at 20° C.

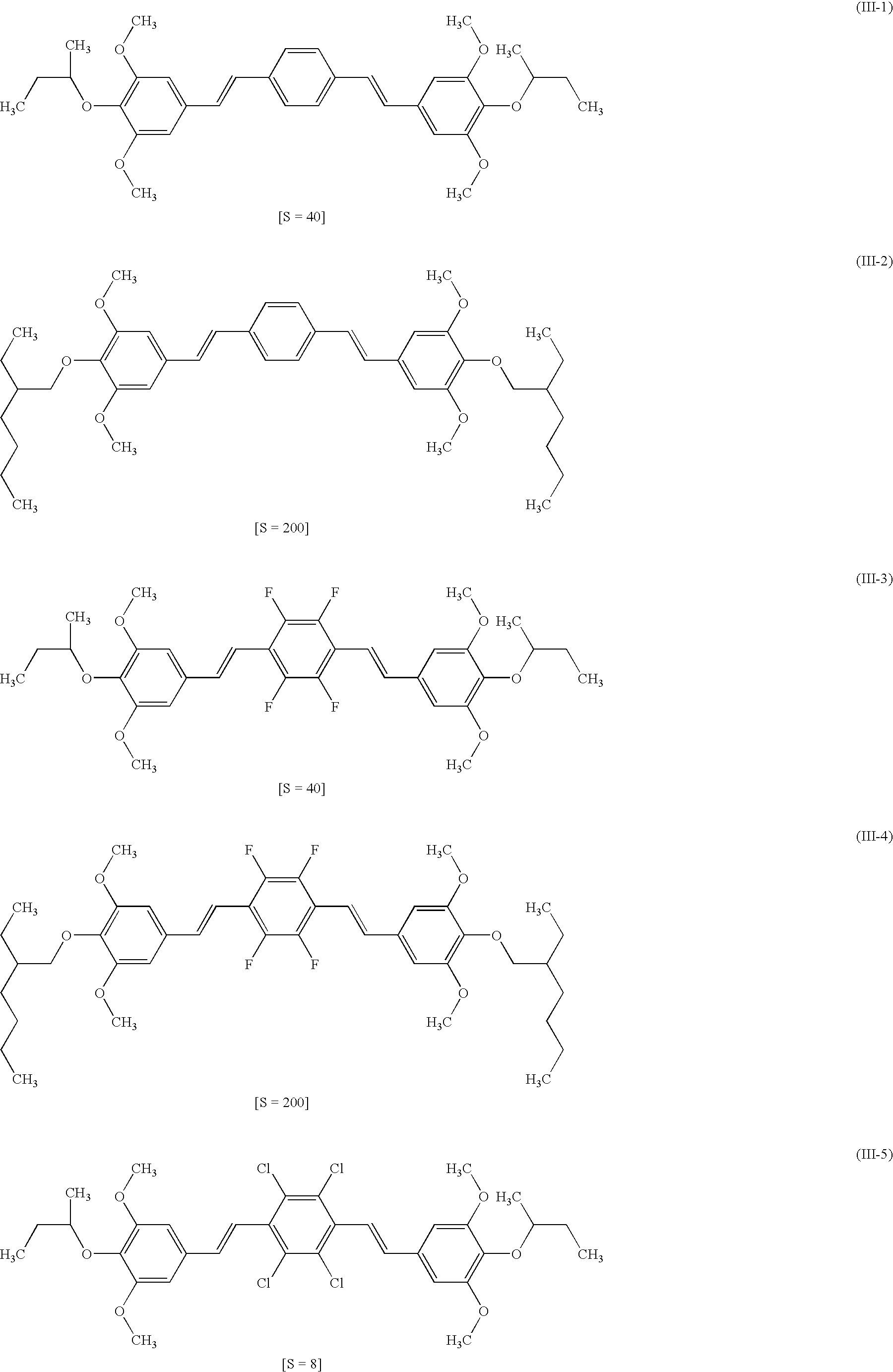

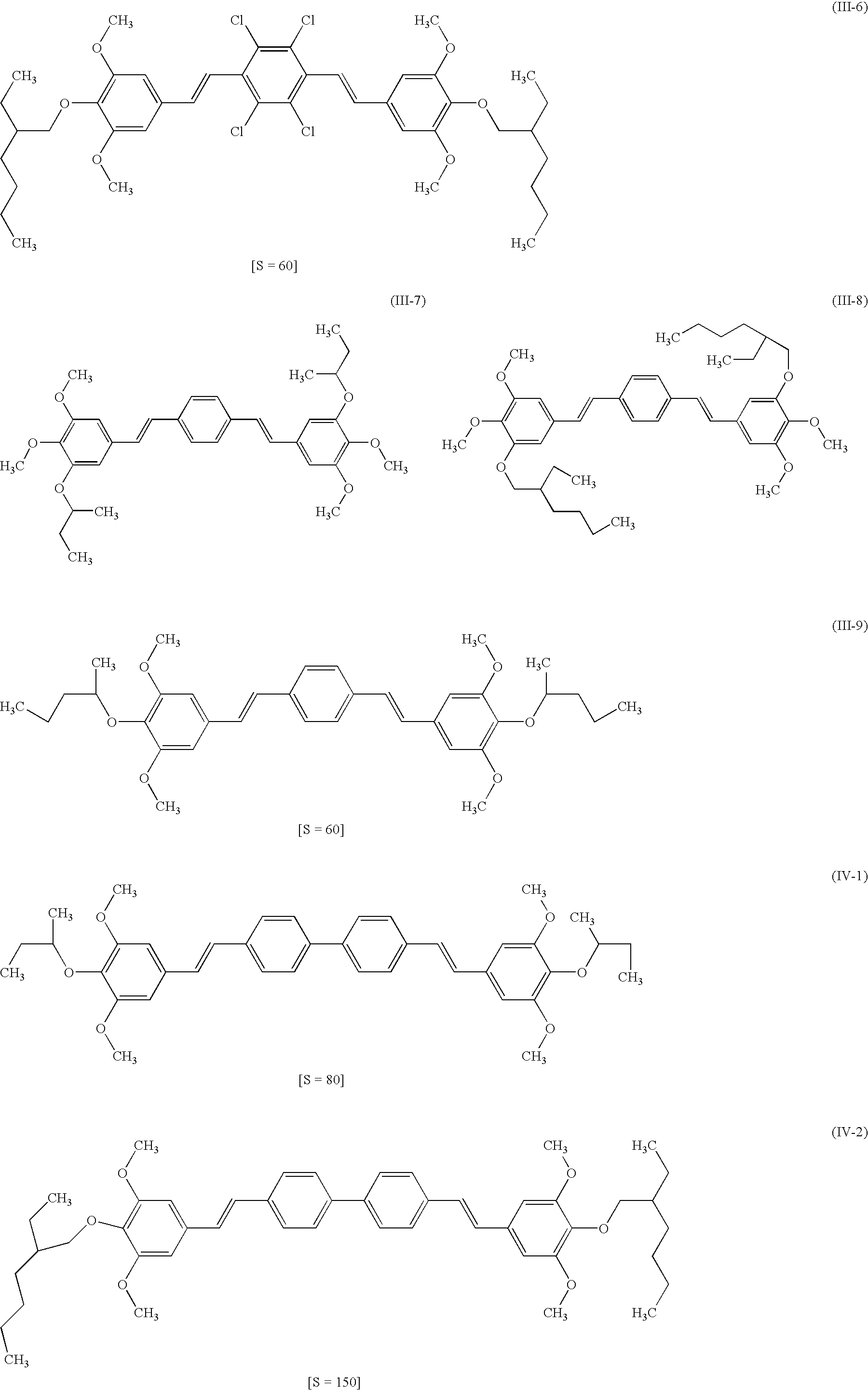

Most sensitizers useful for the preferred embodiments of the present invention can be synthesised by known methods and the synthesis of the highly preferred sensitizers of formulae (IIIa) and (IVa) can be done in analogy to the synthesis of sensitizer (III-1) as disclosed in the following.

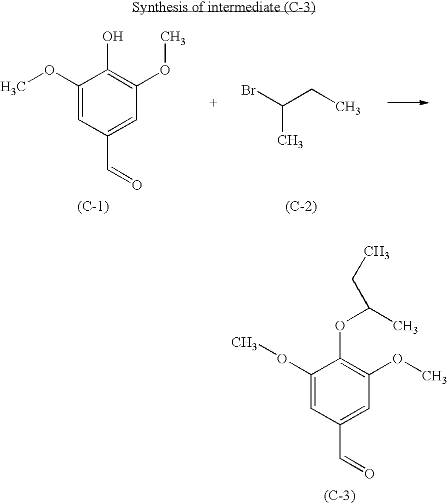

To a mixture of 8.365 kg (45.0 mol) syringaldehyde (C-1) and 1.494 kg (9.0 mol) potassium iodide is added 20.25 L sulfolane at room temperature. After heating up this mixture to 30° C. under nitrogen, 3.12 kg (47.25 mol) of KOH in water and 2.80 kg (20.25 mol) K₂CO₃ are added. After warming the reaction mixture to 75° C., 12.78 kg (90.0 mol) 2-bromo butane (C-2) is added over a period of 30 minutes. Heating at 75° C. is continued for 24 hours, followed by cooling to 25° C. Then 25 L Water is added and the reaction product is extracted with 18 L methyl t-butyl ether (MTBE). The organic phase is consecutively a) two times washed with 6.0 L of a 7.5 wt. % K₂CO₃ solution in water respectively, b) two times washed with 13.5 L of pure water respectively and finally, c) two times washed with 4.5 kg of a 20 wt. % NaCl solution in water respectively. The solvent (MTBE) is removed by distillation under reduced pressure of 50 mBar at 75° C. and thereby are obtained 7.845 kg (theoretical yield of 75%) of the crude intermediate (C-3) as a yellow oil, that is used in the synthesis of (III-1) without further purification.

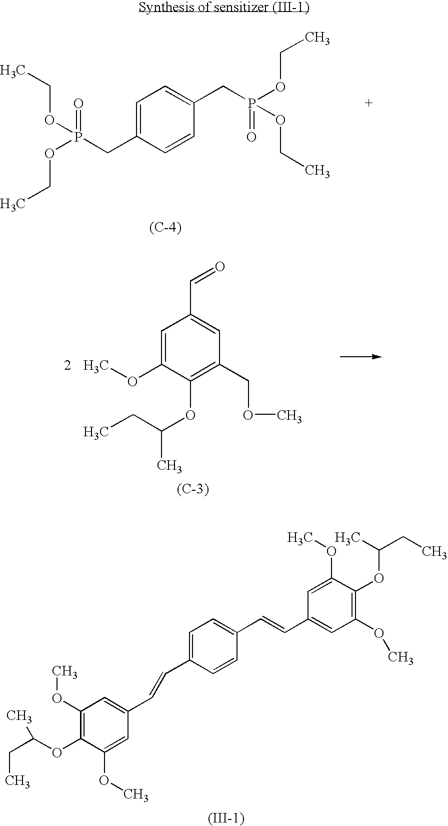

To a mixture of 9.63 kg (25.46 mol) p-xylylene-bis-phosphonate (C-4) and 12.13 kg (50.92 mol) of the crude intermediate (C-3) in 20 L THF, 4.70 kg (71.3 mol) of KOH is added at room temperature. After heating the stirred reaction mixture at reflux for 3.5 hours, the reaction product is precipitated by adding a mixture of 25.2 kg methanol and 9.9 kg water, followed by further cooling to 20° C. The crystalline product (III-1) is filtered off, washed with several portions of methanol/water on the filter and dried at 50° C. The yield is 9.05 kg (theoretical yield of 67%) of (III-1) having a melting point of 154° C.

A suitable synthesis for the p-xylylene-bis-phosphonate (C-4) is known from the literature, e.g. from B. P. Lugovkin and B. A. Arbuzov, Doklady Akademii Nauk SSSR (1948), 59, pages 1301 to 1304.

The photopolymerizable composition according to the present preferred embodiment includes a hexaarylbisimidazole (HABI; dimer of triaryl-imidazole) compound as a photopolymerization initiator.

A procedure for the preparation of hexaarylbisimidazoles is described in DE 1470 154 and their use in photopolymerizable compositions is documented in EP 24 629, EP 107 792, U.S. Pat. No. 4,410,621, EP 215 453 and DE 3 211 312. Preferred derivatives are e. g. 2,4,5,2′,4′,5′-hexaphenylbisimidazole, 2,2′-bis(2-chlorophenyl)-4,5,4′,5′-tetraphenylbisimidazole, 2,2′-bis(2-bromophenyl)-4,5,4′,5′-tetraphenylbisimidazole, 2,2′-bis(2,4-dichlorophenyl)-4,5,4′,5′-tetraphenylbisimidazole, 2,2′-bis(2-chlorophenyl)-4,5,4′,5′-tetrakis(3-methoxyphenyl)bisimidazole, 2,2′-bis(2-chlorophenyl)-4,5,4′,5′-tetrakis(3,4,5-trimethoxyphenyl)-bisimidazole, 2,5,2′,5′-tetrakis(2-chlorophenyl)-4,4′-bis(3,4-dimethoxyphenyl)bisimidazole, 2,2′-bis(2,6-dichlorophenyl)-4,5,4′,5′-tetraphenylbisimidazole, 2,2′-bis(2-nitrophenyl)-4,5,4′,5′-tetraphenylbisimidazole, 2,2′-di-o-tolyl-4,5,4′,5′-tetraphenylbisimidazole, 2,2′-bis(2-ethoxyphenyl)-4,5,4′,5′-tetraphenylbisimidazole and 2,2′-bis(2,6-difluorophenyl)-4,5,4′,5′-tetraphenylbisimidazole. The amount of the HABI photoinitiator typically ranges from about 0.01 to about 30% by weight, preferably from about 0.5 to about 20% by weight, relative to the total weight of the non volatile components of the photopolymerizable composition.

The best results, in particular the highest sensitivity, can be obtained by the combination of an optical brightener as a sensitizer and a hexaarylbisimidazole as a photoinitiator, sensitizers of formulae (III) and (IV) being particularly preferred.

Hexaarylbisimidazole compounds can be used as photoinitiators in combination with further photoinitiators. Known photopolymerization initiators can be used in the composition of the present preferred embodiment in combination with hexarylbisimidazole compounds. Suitable classes include aromatic ketones, aromatic onium salts, organic peroxides, thio compounds, ketooxime ester compounds, borate compounds, azinium compounds, metallocene compounds, active ester compounds, and compounds having a carbon-halogen bond. Many specific examples of such photoinitiators can be found in EP-A 1091247.

Preferably hexaarylbisimidazole compounds are used alone or in combination with aromatic ketones, aromatic onium salts, organic peroxides, thio compounds, ketoxime ester compounds, borate compounds, azinium compounds, active ester compounds, or compounds having a carbon halogen bond.

In a preferred embodiment of the present invention the hexaarylbisimidazole compounds make more than about 50 mol-%, preferably at least about 80 mol-% and particularly preferred at least about 90 mol-% of all the photoinitiators used in the photopolymerizable composition.

The binder can be selected from a wide series of organic polymers. Compositions of different binders can also be used. Useful binders include for example chlorinated polyalkylenes in particular chlorinated polyethylene and chlorinated polypropylene; poly(methacrylic acid) alkyl esters or alkenyl esters in particular poly(methyl (meth)acrylate), poly(ethyl (meth)acrylate), poly(butyl (meth)acrylate), poly(isobutyl (meth)acrylate), poly(hexyl (meth)acrylate), poly((2-ethylhexyl) (meth)acrylate) and poly(alkyl (meth)acrylate); copolymers of (meth)acrylic acid alkyl esters or alkenyl esters with other copolymerizable monomers, in particular with (meth)acrylonitrile, vinyl chloride, vinylidene chloride, styrene and/or butadiene; poly(vinyl chloride) (PVC); vinylchloride/(meth)acrylonitrile copolymers; poly(vinylidene chloride) (PVDC); vinylidene chloride/(meth)acrylonitrile copolymers; poly(vinyl acetate); poly(vinyl alcohol); poly (meth)acrylonitrile; (meth)acrylonitrile/styrene copolymers; (meth)acrylamide/alkyl (meth)acrylate copolymers; (meth)acrylonitrile/butadiene/styrene (ABS) terpolymers; polystyrene; poly(α-methylstyrene); polyamides; polyurethanes; polyesters; cellulose or cellulose compounds like methyl cellulose, ethyl cellulose, acetyl cellulose, hydroxy-(C₁₋₄-alkyl)cellulose, carboxymethyl cellulose; poly(vinyl formal); and poly(vinyl butyral). Particularly suitable are binders that are insoluble in water, but on the other hand are soluble or at least swellable in aqueous-alkaline solutions. Further effective binders are polymers that are soluble in common organic coating solvents.

Particularly suitable for the purpose of the present preferred embodiment are binders containing carboxyl groups, in particular polymers or copolymers containing monomeric units of alpha,beta-unsaturated carboxylic acids and/or monomeric units of alpha,beta-unsaturated dicarboxylic acids, preferably acrylic acid, methacrylic acid, crotonic acid, vinylacetic acid, maleic acid, or itaconic acid. By the term “copolymers” are to be understood in the context of the present preferred embodiment polymers containing units of at least 2 different monomers, thus also terpolymers and higher mixed polymers. Particularly useful examples of copolymers are those containing units of (meth)acrylic acid and units of alkyl (meth)acrylates, allyl (meth)acrylates and/or (meth)acrylonitrile as well as copolymers containing units of crotonic acid and units of alkyl (meth)acrylates and/or (meth)acrylonitrile, and vinylacetic acid/alkyl (meth)acrylate copolymers. Also suitable are copolymers containing units of maleic anhydride or maleic acid monoalkyl esters. Among those are, for example, copolymers containing units of maleic anhydride and styrene, unsaturated ethers or esters or unsaturated aliphatic hydrocarbons and the esterification products obtained from such copolymers. Further suitable binders are products obtainable from the conversion of hydroxyl-containing polymers with intramolecular dicarboxylic anhydrides. Further useful binders are polymers in which groups with acid hydrogen atoms are present, some or all of which are converted with activated isocyanates. Examples of these polymers are products obtained by conversion of hydroxyl-containing polymers with aliphatic or aromatic sulfonyl isocyanates or phosphinic acid isocyanates. Also suitable are polymers with aliphatic or aromatic hydroxyl groups, for example copolymers containing units of hydroxyalkyl (meth)acrylates, allyl alcohol, hydroxystyrene, or vinyl alcohol, as well as epoxy resins, provided they carry a sufficient number of free OH groups.

The organic polymers used as binders have a typical mean molecular weight M_{w} between about 600 and about 200,000, preferably between about 1,000 and about 100,000. Preference is further given to polymers having an acid number between about 10 to about 250, preferably about 20 to about 200, or a hydroxyl number between about 50 and about 750, preferably between about 100 and about 500. The amount of binder(s) generally ranges from about 10 to about 90% by weight, preferably about 20 to about 80% by weight, relative to the total weight of the non-volatile components of the composition.

The polymerizable compound can be selected from a wide series of photo-oxidizable compounds. Suitable compounds contain primary, secondary and in particular tertiary amino groups. Radically polymerizable compounds containing at least one urethane and/or urea group and/or a tertiary amino group are particularly preferred. By the term “urea group” has to be understood in the context of the present preferred embodiment a group of the formula >N—CO—N<, wherein the valences on the nitrogen atoms are saturated by hydrogen atoms and hydrocarbon radicals (with the proviso that not more than one valence on either of the two nitrogen atoms is saturated by one hydrogen atom). However, it is also possible for one valence on one nitrogen atom to be bonded to a carbamoyl (—CO—NH—) group, producing a biuret structure.

Also suitable are compounds containing a photo-oxidizable amino, urea or thio group, which may be also be a constituent of a heterocyclic ring. Compounds containing photo-oxidizable enol groups can also be used. Specific examples of photo-oxidizable groups are triethanolamino, triphenylamino, thiourea, imidazole, oxazole, thiazole, acetylacetonyl, N-phenylglycine, and ascorbic acid groups. Particularly suitable compounds are monomers containing photo-oxidizable groups corresponding to the following formula (XVIII):
R₍ₘ₋ₙ₎Q[(—CH₂—CR¹R²—O)ₐ—CO—NH—(X¹—NH—CO—O)_{b}—X²—(O—CO—CR³═CH₂)_{c}]ₙ (XVIII)
wherein
R represents an alkyl group having 2 to 8 carbon atoms ((C₂-C8) alkyl group), a (C₂-C₈) hydroxyalkyl group, or a (C₆-C₁₄) aryl group,
   Q represents 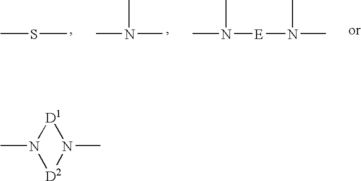
   wherein
   E represents a divalent saturated hydrocarbon group of 2 to 12 carbon atoms, a divalent 5- to 7-membered, saturated iso- or heterocyclic group, which may contain up to 2 nitrogen, oxygen and/or sulfur atoms in the ring, a divalent aromatic mono- or bicyclic isocyclic group of 6 to 12 carbon atoms, or a divalent 5- or 6-membered aromatic heterocyclic group; and
   D¹ and D² independently represent a saturated hydrocarbon group of 1 to 5 carbon atoms,
R¹ and R² independently represent a hydrogen atom, an alkyl or alkoxyalkyl group,
R³ represents a hydrogen atom, a methyl, or ethyl group,
X¹ represents a straight-chained or branched saturated hydrocarbon group of 1 to 12 carbon atoms,
X² represents a (c+1)-valent hydrocarbon group in which up to 5 methylene groups may have been replaced by oxygen atoms,
a is an integer from 0 to 4,
b is 0 or 1,
c is an integer from 1 to 3,
m is an integer from 2 to 4, and
n is an integer from 1 to m.

Compounds of this nature and processes for their preparation are described in EP 287 818. If a compound of general formula (XVIII) contains several radicals R or several radicals according to the structure indicated between square brackets, i. e. if (n−m) >1 and n>1, these radicals can be identical or different from one another. Compounds according to formula (XVIII) wherein n=m are particularly preferred. In this case, all radicals contain polymerizable groups. Preferably, the index a is 1; if several radicals are present, a cannot be 0 in more than one radical. If R is an alkyl or hydroxyalkyl group, R generally contains 2 to 6, particularly 2 to 4 carbon atoms. Aryl radicals R are in general mononuclear or binuclear, preferably however mononuclear, and may be substituted with (C₁-C₅) alkyl or (C₁-C₅) alkoxy groups. If R¹ and R² are alkyl or alkoxy groups, they preferably contain 1 to 5 carbon atoms. R³ is preferably a hydrogen atom or a methyl group. X¹ is preferably a straight-chained or branched aliphatic and/or cycloaliphatic radical of preferably 4 to 10 carbon atoms. In a preferred embodiment, X² contains 2 to 15 carbon atoms and is in particular a saturated, straight-chained or branched aliphatic and/or cycloaliphatic radical containing this amount of carbon atoms. Up to 5 methylene groups in these radicals may have been replaced by oxygen atoms; in the case of X₂ being composed of pure carbon chains, the radical generally has 2 to 12 carbon atoms, preferably 2 to 6 carbon atoms. X₂ can also be a cycloaliphatic group of 5 to 10 carbon atoms, in particular a cyclohexane diyl group. The saturated heterocyclic ring formed by D¹, D² and both nitrogen atoms generally has 5 to 10 ring members in particular 6 ring members. In the latter case the heterocyclic ring is preferably a piperazine and the radical derived therefrom a piperazine-1,4-diyl radical. In a preferred embodiment, radical E is an alkane diyl group which normally contains about 2 to 6 carbon atoms. Preferably the divalent 5- to 7-membered, saturated, isocyclic group E is a cyclohexane diyl group, in particular a cyclohexane-1,4-diyl group. The divalent, isocyclic, aromatic group E is preferably an ortho-, meta- or para-phenylene group. The divalent 5- or 6-membered aromatic heterocyclic group E, finally, contains preferably nitrogen and/or sulphur atoms in the heterocyclic ring. c is preferably 1, i.e., each radical in the square bracket generally contains only one polymerizable group, in particular only one (meth)acryloyloxy-group.

The compounds of formula (XVIII) wherein b=1, which accordingly contain two urethane groups in each of the radicals indicated in the square brackets, can be produced in a known way by conversion of acrylic esters or alkacrylic esters which contain free hydroxyl groups with equimolar amounts of diisocyanates. Excess isocyanate groups are then, for example, reacted with tris(hydroxyalkyl)amines, N,N′-bis(hydroxyalkyl) piperazines or N,N,N′,N′-tetrakis(hydroxyalkyl)alkylenediamines, in each of which individual hydroxyalkyl groups may have been replaced by alkyl or aryl groups R. If a=0, the result is a urea grouping. Examples of the hydroxyalkylamine starting materials are diethanolamine, triethanolamine, tris(2-hydroxypropyl)amine, tris(2-hydroxybutyl)amine and alkyl-bis-hydroxyalkylamines. Examples of suitable diisocyanates are hexamethylene diisocyanate, 2,2,4-trimethylhexamethylene diisocyanate, 1,4-cyclohexylene diisocyanate (=1,4-diisocyanatocyclohexane), and 1,1,3-trimethyl-3-isocyanatomethyl-5-isocyanatocyclohexane. The hydroxy-containing esters used are preferably hydroxyethyl (meth)acrylate, hydroxypropyl (meth)acrylate, and hydroxyisopropyl (meth)acrylate.

The polymerizable compounds of formula (XVIII) wherein b=0 are prepared converting the above-described hydroxyalkylamino compounds with isocyanate-containing acrylic or alkacrylic esters. A preferred isocyanate-containing ester is isocyanoto-ethyl (meth)acrylate.

Further polymerizable compounds including photooxidisable groups suitable for the purpose of the preferred embodiments are compounds according to the following formula (XIX):
R₍ₘ₋ₙ₎Q[(—CH₂—CR¹R²—O)_{a′}—(CH₂—CH[CH₂—O—CO—CR³═CH₂]—O)_{b′}—H]ₙ (XIX)
wherein a′ and b′ independently represent integers from 1 to 4 and Q, R¹, R², R³, n and m have the same meaning as above and Q can also be a group of the formula >N-E′-N< wherein the radical E′ corresponds to the following formula (XX):
—CH₂—CH(OH)—CH₂—[O-(p)C₆H₄—C(CH₃)₂-(p)C₆H₄—CH₂—CH₂—CH(OH)—CH₂—]_{c} (XX)
wherein c has the same meaning as in formula (I) and (p)C₆H₄ represents para-phenylene.

The compounds of formula (XIX) can be prepared analogously to those of formula (XVIII), except that the conversion products of hydroxyalkyl acrylates or alkacrylates and diisocyanates are replaced by the corresponding acrylic and alkacrylic glycide esters. Compounds of formula (XX) and processes to their preparation are disclosed in EP 316 706.

Further useful polymerizable compounds containing photooxidisable groups are acrylic and alkacrylic esters of the following formula (XXI):
Q′[(—X¹′—CH₂—O)ₐ—CO—NH(—X¹—NH—CO—O)_{b}—X²—O—CO—CR³═CH₂]ₙ (XXI)
wherein
Q′ represents 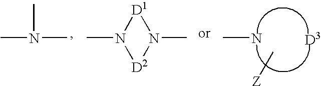
   wherein D¹ and D² independently represent a saturated hydrocarbon group of 1 to 5 carbon atoms and D³ represents a saturated hydrocarbon group of 4 to 8 carbon atoms, which together with the nitrogen atom forms a 5- or 6-membered heterocyclic ring; X¹′ represents —CᵢH₂ᵢ— or 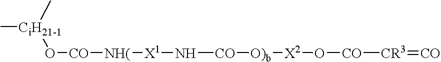
Z represents a hydrogen atom or a radical of the following formula:
   —CₖH₂ₖ—O—CO—NH(—X¹—NH—CO—O)_{b}—X²—O—CO—CR³═CH_{2;}
i,k independently represent integers from 1 to 12;
n′ represents an integer from 1 to 3; and
a is 0 or 1; provided that a is 0 in at least one of the radicals bonded to Q;
X¹, R³, a and b have the same meaning as given in the above formula (VIII); and
X² represents a divalent hydrocarbon group in which up to 5 methylene groups may be replaced by oxygen atoms.

In formula (XXI) index a is preferably 0 or 1 and i preferably represents a number between 2 and 10. Preferred radicals Q are piperazine-1,4-diyl (D¹=D²=CH₂—CR₂), piperidine-1-yl (D³=(CH₂)₅, Z=H) and 2-(2-hydroxyethyl)-piperidine-1-yl (D³ =(CH₂)₅, Z=CH₂CH₂OH).

Of the compounds of formula (XXI), those which apart from a urea group contain at least one urethane group are preferred. Here again, by the term “urea group” has to be understood the group of formula >N—CO—N< already mentioned above. Compounds of formula (XXI) and processes for their preparation are disclosed in EP 355 387.

Also suitable polymerizable compounds are reaction products of mono- or diisocyanates with multifunctional alcohols, in which the hydroxy groups are partly or completely esterified with (meth)acrylic acid. Preferred compounds are materials, which are synthesized by the reaction of hydroxyalkyl-(meth)acrylates with diisocyanates. Such compounds are basically known and for instance described in DE 28 22 190 and DE 20 64 079.

The amount of polymerizable compound including photooxidisable groups generally ranges from about 5 to about 75% by weight, preferably from about 10 to about 65% by weight, relative to the total weight of the non volatile compounds of the photopolymerizable composition.

Moreover, the composition can contain polyfunctional (meth)acrylate or alkyl(meth)acrylate compounds as crosslinking agents. Such compounds contain more than 2, preferably between 3 and 6 (meth)acrylate and/or alkyl(meth)acrylate groups and include in particular (meth)acrylates of saturated aliphatic or alicyclic trivalent or polyvalent alcohols such as trimethylol ethane, trimethylol propane, pentaerythritol, or dipentaerythritol.

The total amount of polymerizable compounds generally ranges from about about 10 to about 90% by weight, preferably from about 20 to about 80% by weight, relative to the total weight of the non volatile components of the photopolymerizable composition.

The following specific example is a prefered polymerizable compound:

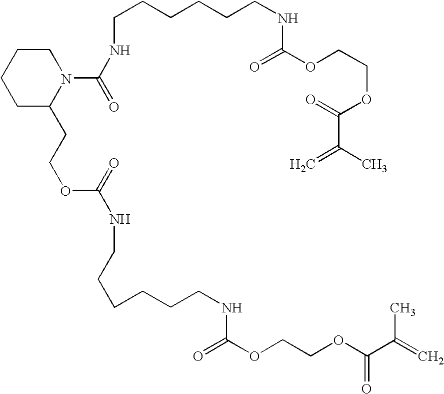

In order to achieve a high sensitivity, it is advantageous to add a radical chain transfer agent as described in EP 107 792 to the photopolymerizable composition. The preferred chain transfer agents are sulfur containing compounds, especially thiols like e. g. 2-mercaptobenzothiazole, 2-mercaptobenzoxazole or 2-mercapto-benzimidazole. The amount of chain transfer agent generally ranges from about 0.01 to about 10% by weight, preferably from about 0.1 to about 2% by weight, relative to the total weight of the non volatile components of the photopolymerizable composition.

Optionally, pigments, e.g., predispersed phthalocyanine pigments, can be added to the composition for dyeing the composition and the layers produced therewith. Their amount generally ranges from about about 1 to about 20% by weight, preferably from about 2 to about 15% by weight and particularly preferred from about 2 to about 10% by weight related to the total weight of the non volatile components of the composition. Particularly suitable predispersed phthalocyanine pigments are disclosed in DE 199 15 717 and DE 199 33 139. Preference is given to metal-free phthalocyanine pigments.

In order to adjust the photopolymerizable composition according to the present preferred embodiment to specific needs, thermal inhibitors or stabilizers for preventing thermal polymerization may be added. Furthermore additional hydrogen donors, dyes, colored or colorless pigments, color formers, indicators, and plasticisers may be present. These additives are convieniently selected so that they absorb as little as possible in the actinic range of the imagewise applied radiation.

The photopolymerizable composition is applied to the support by processes which are known per se to the person skilled in the art. In general, the components of the photopolymerizable composition are dissolved or dispersed in an organic solvent or solvent mixture, the solution or dispersion is applied to the intended support by pouring on, spraying on, emersion, roll application or in a similar manner and the solvents are removed during the subsequent drying.

Known supports can be used for the photopolymer printing plate, like, e.g., foils, tapes, or plates made of metal or plastics and in the case of screen-printing also of Perlon gauze. Preferred metals are aluminium, aluminium alloys, steel and zinc, aluminium and aluminium alloys being particularly preferred. Preferred plastics are polyester and cellulose acetates, polyethyleneterephthalate (PET) being particularly preferred.

In most cases, it is preferred to treat the surface of the support mechanically and/or chemically and/or electrochemically to optimally adjust the adherence between the support and the photosensitive coating and/or to reduce the reflection of the imagewise exposed radiation on the surface of the support (antihalation).

The most preferred support to be used is made of aluminium or an aluminium alloy, its surface is electrochemically roughened, thereafter anodized and optionally treated with a hydrophilizing agent like, e.g., poly(vinylphosphonic acid).

The protective overcoat includes at least one type of poly(vinyl alcohol), wherein the mean degree of saponification is less than about 93 mol-%, preferably a mixture of at least two types of poly(vinyl alcohol) wherein the overall mean degree of saponification of all the polyvinylalcohols is less than about 93 mol-%.

The degree of saponification is related to the production of poly(vinyl alcohols). As the monomer of poly(vinyl alcohol), vinyl alcohol, is nonexistent, only indirect methods are available for the production of poly(vinyl alcohol). The most important manufacturing process for poly(vinyl alcohol) is the polymerization of vinyl esters or ethers, with subsequent saponification or transesterification. The preferred starting material for the poly (vinyl alcohol) is a vinyl alcohol esterified by a mono carboxylic acid and in particular vinyl acetate, but derivatives of vinyl acetate, vinyl esters of di carboxylic acids, vinyl ethers and the like can also be used. The degree of saponification, as defined in the present invention, is the molar degree of hydrolysis irrespective of the process used for the hydrolysis. Pure poly(vinyl alcohol) has, e.g., a degree of saponification of 100 mol-%, but commercial products often have a degree of saponification of 98 mol-%. The poly(vinyl alcohols) contain mainly 1,3-diol units, but may also contain small amounts of 1,2-diol units. In the partially saponified poly(vinyl alcohols) the ester or the ether group can be distributed statistically or blockwise. Preferred partially saponified poly(vinyl alcohols) have a viscosity of a 4% aqueous solution at 20° C. of about 4 to about 60 mPa·s, preferably of about 4 to about 20 mPa·s and in particular of about 4 to about 10 mPa—s.

Preferred poly(vinyl alcohols) are commercially available, e.g., under the tradename Mowiol. Those products are characterised by two appended numbers, meaning the viscosity and the degree of saponification. For example, Mowiol 8-88 or Mowiol 8/88 mean a poly(vinyl alcohol) having as 4% aqueous solution at 20° C. a viscosity of ca 8 mPa·s and a degree of saponification of 88 mol-%. Although the use of only one type of poly(vinyl alcohol) is sufficient to achieve an advantage, it is preferred to use a mixture of two or more compounds, because this allows a more accurate adjustment and a better optimization of further properties of the printing plate precursor. Preferably poly(vinyl alcohols) differing in viscosity as defined above and/or in saponification degree are combined. Particularly preferred are mixture of poly(vinyl alcohols) that differ in viscosity of their 4% aqueous solutions at 20° C. for at least 2 mPa·s or that differ in saponification degree for at least 5 mol-%. Most preferred are mixtures including at least 3 types of poly(vinyl alcohols), wherein at least two compounds differ in viscosity as defined above for at least 2 mPa·s and at least two compounds differ in saponification degree for at least 5 mol-%.

According to a preferred embodiment of the present invention, a mixture of at least two types of polyvinylalcohol are used wherein the overall mean saponification degree of all polyvinyl alcohols used in the protective layer has to be less than about 93 mol-%. Thereby a higher Tₘₐₓ(‘asteroid’-free) is achieved and also an improved pre-heat latitude with respect to the dot gain, i.e., the dot gain is less influenced by the pre-heat temperature compared to higher overall mean saponification degrees. In a particular preferred embodiment of the present invention the overall mean saponification degree ranges from about 71 mol-% to less than about 93 mol-% and in particular from about 80 mol-% to about 92.9 mol-%.

As long as the mean overall saponification limit of about 93 mol-% is not reached, one of the poly(vinyl alcohols) used in a mixture can have a mean saponification degree of more than about 93 mol-% and even up to 100 mol-%.

The overall mean saponification degree of the poly(vinyl alcohols) used in the protective overcoat of a printing plate precursor can be determined experimentally via ¹³C-NMR. To measure the ¹³C-NMR spectra, approximately 200 mg of the protective overcoat are dissolved in 1.0 ml DMSO and from this solution a 75 MHz ¹³C-NMR spectrum is taken, whose resonances can easily be interpreted and allow to calculate the degree of saponification. Such values are listed in the Examples, in Table 3, as experimental values. A good correlation is obtained between the experimental values and the values known from the product specification of the poly(vinyl alcohols). The latter values are hereinafter called theoretical values of the mean saponification degree and can easily be calculated, when mixture of poly(vinyl alcohols) are used.

Preferably, poly(vinyl alcohol)s are about 50 to about 99.9 weight percent (wt. %) relative to the total weight of the non-volatile compounds of the protective overcoat.

The protective layer may further contain a poly(vinyl pyrrolidone) in an amount from 0 to about 10 parts by weight of the poly(vinyl alcohol) used, from 0 to about 3 parts by weight being particularly preferred. Most preferred no poly(vinyl pyrrolidone)compounds are used.

Apart from poly(vinyl alcohol)s and poly(vinyl pyrrolidone), other water soluble polymers can be further added to the layer such as poly(ethylene oxide), gelatin, gum arabic, oxygen binding polymers with aliphatic amine groups known from EP 352 630 B1, methyl vinylether/maleic anhydride copolymers, poly(carboxylic acids), copolymers of ethylene oxide and poly(vinyl alcohol), carbon hydrates, hydroxy ethyl cellulose, acidic cellulose, cellulose, poly(arylic acid) and mixtures of these polymers.

In addition to the poly(vinyl alcohol) and polyvinylpyrrolidone and the optional watersoluble polymers disclosed above, known ingredients of protective layers can be used.

Examples of known ingredients suitable for the protective layer are surface wetting agents, coloring agents, complexants, polyethylenimines, and biocides.

The protective layer has to be transparent for actinic light. Preferably it is homogeneous, substantially impermeable to oxygen, waterpermeable, and can be washed off preferably with conventional developer solutions used to form a printing relief after imagewise exposure of the photosensitive layer. The photosensitive layer is removed imagewise, whereas the protective layer is removable over the entire area of the element created. The wash-off of the protective layer can be done in a separate step, but can be done during the development step as well.

The dry coating weight of the protective overcoat can be measured by the following procedure. A plate is exposed for 4 hours to daylight. Next the plate is pre-heated between 104° C. and 127° C. (temperature measured via a thermostrip (THERMAX commerically available from TMC) at the back of the plate). The plate is cut to a size of 100 mm×100 mm and weighted on an analytical balance with 0.01 mg accuracy (=Weight A). Next the protective overcoat is washed off with water (25° C.) for 2 minutes. Than the plate is rinsed with demineralised water and dried in an oven at 100° C. After drying the plate is allowed to cool down to room temperature, and the weight is determined using the same analytical balance as described earlier (=Weight B). The dry coating weight in g/m² of the protective overcoat is calculated using the formula below:
Dry coating weight (g/m²)=100×(Weight A−Weight B)

The protective layer can be coated on the photosensitive layer with known techniques and the coating solution preferably contains water or a mixture of water and an organic solvent. To allow a better wetting, the coating solution preferably contains, related to the solid content, up to labout 0 wt. %, and particularly preferred up to about 5 wt. % of a surface active agent. Suitable representatives of surface active agents include anionic, cationic, and nonionic surface active agents like sodium alkylsulfates and -sulfonates having 12 to 18 carbon atoms, an example of which is sodium dodecylsulfate, N-cetyl- and C-cetyl betaine, alkylaminocarboxylate and -dicarboxylate, and polyethylene glycols with a mean molar weight up to 400.

In addition, further functions can be added to the protective layer. For example, it can be possible to improve the safelight suitability without decreasing the sensitivity of the layer by adding a coloring agent, e.g., a water-soluble dye, that has excellent transmission to the light having a wavelength of about 300 to about 450 nm and that absorbs the light having a wavelength of about 500 nm or more. This principle can easily be varied for different wavelengths to adjust the effective spectral sensitivity distribution of the printing plate precursor as needed.

Another preferred embodiment of the present invention also relates to a method of making a lithographic printing plate including the steps of providing a photopolymer printing plate precursor as defined in any of the preceding preferred embodiments, exposing the printing plate precursor with a laser having an emission wavelength in the range from about 300 to about 450 nm, heating the plate to a temperature, when measured at the back of the plate, from about 90° C. to about 150° C., washing off the protective coating and processing the printing plate precursor in an aqueous alkaline developer.

In preferred embodiment of the process of the present invention the exposure is done with a laser having an emission wavelength in the range from about 380 to about 430 nm, in particular in the range from about 390 to about 420 nm, and the exposure is carried out at an energy density, measured on the surface of the plate, of about 100 μJ/cm² or less.

The processing of the printing plate precursor is done in the usual manner. After image-wise exposure a pre-heat step is performed to improve the crosslinking of the photosensitive layer. Usually the pre-heat step is then followed by the development step, wherein the complete overcoat layer and the unexposed part of the photosensitive layer are removed. The removal (wash-off) of the overcoat layer and the development of the photosensitive layer can be done in two separate steps in this order, but can also be done in one step simultaneously. Preferably the overcoat layer is washed-off with water before the development step. The wash-off can be done with cold water, but it is preferred to use hot water to accelerate the process. What remains on the support after the development step are the exposed and thereby photopolymerized parts of the photosensitive layer. The developer solution used for the development of the exposed printing plate precursors preferably is an aqueous alkaline solution having a pH of at least about 11, a pH from about 11.5 to about 13.5 being particularly preferred. The developer solution can contain a small percentage, preferably less than about 5 wt. %, of an organic, water-miscible solvent. To adjust the pH of the solution, an alkali hydroxide is preferably used.

Examples of preferred, additional ingredients of the developer solution include alone or in combination alkali phosphates, alkali carbonates, alkali bicarbonates, an organic amine compound, alkali silicates, buffering agents, complexants, defoamers, surface active agents, and dyes, but the suitable ingredients are not limited to the preferred examples and further ingredients can be used.

The method of development employed is not particularly limited, and may be conducted by soaking and shaking the plate in a developer, physically removing non-image portions while being dissolved in a developer by means of, e.g., a brush, or spraying a developer onto the plate so as to remove non-image portions. The time for development is selected depending upon the above method used so that the non-image portions can adequately be removed, and is optionally selected within a range of about 5 seconds to about 10 minutes.

After the development, the plate may be subjected to a hydrophilic treatment by use of, e.g., gum arabic optionally applied to the printing plate as the case requires (gumming step).

### EXAMPLES

### Components Used in the Examples

(A) A solution containing 32.4 wt. % of a methylmethacrylate/methacrylic acid copolymer (ratio methylmethacrylate/methacrylic acid of 85:15 by weight; acid number: 110 mg KOH/g) in 2-butanone (viscosity 105 mm²/s at 25° C.).
(B) A solution containing 88.2 wt. % of a reaction product from 1 mole of 2,2,4-trimethyl-hexamethylenediisocyanate and 2 moles of hydroxyethylmethacrylate (viscosity 3.30 mm²/s at 25° C.).
(C) A solution in 2-butanone containing 30.1 wt. % of a reaction product from 1 mole of hexamethylenediisocyanate, 1 mole of 2-hydroxyethylmethacrylate and 0.5 mole of 2-(2-hydroxyethyl)-piperidine (viscosity 1.7 mm²/s at 25 ° C.).
(D) Sensitizer (III-1).
(E) HELIOGENE BLUE D 7490® dispersion (9.9 wt. %, viscosity 7.0 mm²/s at 25 ° C.), trade name of BASF AG, as disclosed in EP 1 072 956.
(F) 2,2′-Bis(2-chlorophenyl)-4,4′,5,5′-tetraphenyl-1,2-bisimidazole.
(G) 2-Mercaptobenzothiazole.
(H) EDAPLAN LA 411® (commercially available from Münzig Chemie;

1 wt. % in DOWANOL PM® (trade mark of Dow Chemical Company)); silicon surfactant.
(I) 2-Butanone.
(J) Propyleneglycol-monomethylether (DOWANOL PM®, trade mark of Dow Chemical Company).
(K) Partially hydrolyzed poly(vinyl alcohol) (degree of saponification 88 mol-%, viscosity 4 mPa·s in an aqueous solution of 4 wt. % at 20° C.).
(L) Fully hydrolyzed poly(vinyl alcohol) (degree of saponification 98 mol-%, viscosity 6 mPa·s in an aqueous solution of 4 wt. % at 20° C.).
(M) Partially hydrolyzed poly(vinyl alcohol) (degree of saponification 88 mol-%, viscosity 8 mPa·s in an aqueous solution of 4 wt. % at 20° C.).
(N) Acticide LA1206; a biocide commercially available from Thor based on a mixture of 5-chlor-2-methyl-2H-isothiazol-3-on and 2-Br-2-nitropropanediol.
(O) Metolat FC 355 (ethoxylated ethylenediamine; commercially available from Münzig Chemie): 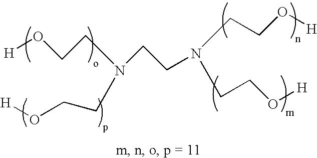
(P) Lutensol A8 (90 wt. %) (surface active agent; commercially available from BASF).
(Q) Water.
(R) Lupasol P (polyethylenimine 50 wt. % in water; commercially available from BASF).

### Comparative Example 1

A) Preparation and Coating of the Photosensitive Layer

A composition was prepared (pw=parts per weight; wt. %=weight percentage) by mixing the ingredients as specified in Table 1. This composition was coated on an electrochemically roughened and anodically oxidized aluminum sheet, the surface of which has been rendered hydrophilic by treatment with an aqueous solution of poly(vinylphosphonic acid) (oxide weight 3 g/m²) and was dried at 105° C. The resulting thickness of the layer was 1.5 g/m².

TABLE 1
Composition of the photosensitive coating solution

| | Parts per |
|---|---|
| Component | weight (g) |
| (A) | 181.70 |
| (B) | 36.14 |
| (C) | 381.23 |
| (D) | 10.97 |
| (E) | 207.11 |
| (F) | 16.58 |
| (G) | 0.77 |
| (H) | 25.50 |
| (I) | 650.07 |
| (J) | 1489.95 |

B) Preparation and Coating of the Protective Overcoat Layer

On top of the photosensitive layer a solution in water (containing 4.0 wt. %) of the composition as defined in Table 2 was coated and then was dried at 120° C. for 2 minutes.

TABLE 2
Coating composition of the protective overcoat

| | Parts per |
|---|---|
| Component | weight (g) |
| (K) | 550.67 |
| (L) | 475.82 |
| (M) | 237.91 |
| (N) | 2.56 |
| (O) | 12.11 |
| (P) | 1.03 |
| (Q) | 30719.90 |

The protective overcoat had a dry coating weight of 1.90 g/m².

Evaluation of the Pre-heat Latitude

Three plates were imaged with a 40% screen (110 lpi) at the appropriate exposure, i.e., sensitivity of the plate (minimum energy density to expose 2 solid steps (0.3 optical density) of an UGRA 1982 step wedge). For this example the sensitivity is 26 μJ/cm². The imaging was carried out with an experimental violet platesetter device (flat bed system) equipped with a violet laser diode emitting between 392 to 417 nm. The following imaging conditions were used:

Scanning speed: 1000 m/s

Variable image plane power: 0 to 10.5 mW

Spot diameter: 20 μm

Addressability: 1270 dpi

After the imaging step the plate was processed in an Agfa VSP85 processor at a speed of 1.2 m/min. During the processing the plate is first heated (pre-heat step), next the protective overcoat is washed off and the photolayer is processed in a water based alkaline developer (Agfa EN 231C) at 28° C. After a water rinsing and gumming step the printing plate is ready to use.

The three plates were processed at different pre-heat temperatures (Tₚᵣₑ₋ₕₑₐₜ): 99° C., 104° C., 116° C., 121° C., 127° C., 138° C. and 143° C. (i.e., temperature measured at the back of the plate with a thermostrip). The temperature at the back of the plate was varied by varying the temperature of the ceramic heater of the processor.

Next the image was visually inspected for ‘asteroids’; these are small image defects which appear in the non-image areas of the 40% screen (110 lpi). The better the pre-heat latitude, the higher the maximum ‘asteroid’-free pre-heat temperature (Tₘₐₓ(‘asteroid’-free)). The results of the visual inspection for each pre-heat temperature are summarized in Table 3.

TABLE 3
occurence of asteroids versus pre-heat temperatures

| | 99° | 104° | 116° | 121° | 127° | 138° | 143° |
|---|---|---|---|---|---|---|---|
| | C. | C. | C. | C. | C. | C. | C. |
| Asteroids | No | No | No | Yes | Yes | Yes | Yes |

From the results listed in Table 3 it can be seen, that the maximum ‘asteroid’-free pre-heat temperature (Tₘₐₓ(‘asteroid’-free)) for the comparative example is 116° C.

### Examples 1 to 4

The preparation of the printing plate precursor was identical to the comparative example 1, with the exception, that a radical stabilizer was added to the photolayer. The photolayer compositions are listed in table 4.

TABLE 4
Composition of the photosensitive coating solution

| | Example 1 | Example 2 | Example 3 | Example 4 |
|---|---|---|---|---|
| | Parts per | Parts per | Parts per | Parts per |
| Component | weight (g) | weight (g) | weight (g) | weight (g) |
| (A) | 181.31 | 180.92 | 181.31 | 181.62 |
| (B) | 36.14 | 36.14 | 36.14 | 36.14 |
| (C) | 381.23 | 381.23 | 381.23 | 381.23 |
| (D) | 10.97 | 10.97 | 10.97 | 10.97 |
| (E) | 207.11 | 207.11 | 207.11 | 207.11 |
| (F) | 16.58 | 16.58 | 16.58 | 16.58 |
| (G) | 0.77 | 0.77 | 0.77 | 0.77 |
| (H) | 25.50 | 25.50 | 25.50 | 25.50 |
| (I) | 650.34 | 651.60 | 650.34 | 650.07 |
| (J) | 1489.95 | 1489.95 | 1489.95 | 1489.95 |
| (ST-18) | 0.13 | 0.26 | — | — |
| (ST-21) | — | — | 0.13 | — |
| (ST-6) | — | — | — | 0.03 |

The pre-heat latitude of the printing plate precursor was evaluated as described in comparative example 1. Both the sensitivity and the Tₘₐₓ(‘asteroid’-free) were determined. The results are summarised in Table 5.

TABLE 5

| | Comp. | | | | |
|---|---|---|---|---|---|
| | Example | Example | Example | Example | Example |
| | 1 | 1 | 2 | 3 | 4 |
| sensitivity | 26 | 36 | 39 | 35 | 32 |
| (μJ/cm²) | | | | | |
| Tₘₐₓ | 116° C. | 127° C. | 127° C. | 127° C. | 127° C. |
| (‘asteroid’- | | | | | |
| free) | | | | | |

The examples 1 to 4 demonstrate that the use of radical stabilizing compounds in the photolayer leads to an improved pre-heat latitude.

### Examples 5 to 10 and Comparative Examples 2 to 4

Preparation and Coating of the Photosensitive Layer

A composition was prepared (pw=parts per weight; wt. %=weight percentage) by mixing the ingredients as specified in Table 6. This composition was coated on an electrochemically roughened and anodically oxidized aluminum sheet, the surface of which has been rendered hydrophilic by treatment with an aqueous solution of poly(vinylphosphonic acid) (oxide weight 3 g/m²) and was dried at 105° C. The resulting thickness of the layer was 1.5 g/m².

TABLE 6
Composition of the photosensitive coating solution

| | Parts per |
|---|---|
| Component | weight (g) |
| (A) | 552.37 |
| (B) | 109.79 |
| (C) | 1147.50 |
| (D) | 32.90 |
| (E) | 598.83 |
| (F) | 49.73 |
| (G) | 2.30 |
| (H) | 76.50 |
| (I) | 1937.38 |
| (J) | 452.25 |
| (ST-18) | 0.38 |

Preparation and Coating of the Protective Overcoat Layer

On top of the photosensitive layer a solution in water (containing 4.0 wt. %) of the composition as defined in Table 7 was coated and then was dried at 120° C.

TABLE 7
Coating composition of the protective overcoat

| | Parts per |
|---|---|
| Component | weight (g) |
| (K) | 681.44 |
| (L) | 594.77 |
| (M) | 297.39 |
| (N) | 3.20 |
| (R) | 16.00 |
| (P) | 16.89 |
| (Q) | 38390.31 |

The protective overcoat for the examples and the comparative examples was coated at different dry coating weights as defined in Table 8.

The pre-heat latitude of the printing plate precursors was evaluated as described in comparative example 1. Both the sensitivity and the Tₘₐₓ(‘asteroid’-free) were determined. Additionally the plate was inspected for defects, i.e., non-hardened defects in an image area. The results are summarised in Table 8.

TABLE 8

| | Comp. | Ex. | Ex. | Ex. | Ex. | Ex. | Ex. | Comp. | Comp. |
|---|---|---|---|---|---|---|---|---|---|
| | Ex. 2 | 5 | 6 | 7 | 8 | 9 | 10 | Ex. 3 | Ex. 4 |
| dry coating weight | 0.25 | 0.50 | 0.75 | 1.00 | 1.25 | 1.50 | 1.75 | 2.00 | 2.25 |
| of protective layer | | | | | | | | | |
| (g/m²) | | | | | | | | | |
| image defects | YES | NO | NO | NO | NO | NO | NO | NO | NO |
| sensitivity (μJ/cm²) | 52 | 39 | 39 | 39 | 39 | 39 | 39 | 39 | 39 |
| Tₘₐₓ | 143° C. | 143° C. | 143° C. | 143° C. | 143° C. | 143° C. | 127° C. | 121° C. | 121° C. |
| (‘asteroid’-free) | | | | | | | | | |

The examples demonstrate that reducing the dry coating weight below about 2.0 g/m² leads to a significant improvement in pre-heat latitude. At a low dry coating weight of about 0.25 g/m² the image areas show defects (non-hardened areas in image areas) and the sensitivity is slightly reduced (i.e., a higher value is obtained).

While preferred embodiments of the present invention have been described above, it is to be understood that variations and modifications will be apparent to those skilled in the art without departing the scope and spirit of the present invention. The scope of the present invention, therefore, is to be determined solely by the following claims.

1-41. (canceled)

42. A photopolymer printing plate precursor comprising, in this order:
a support, a photosensitive coating, and a protective coating; wherein
the photosensitive coating includes a composition that is photopolymerizable upon absorption of light, the composition including a binder, a polymerizable compound, a radical stabilizer, a sensitizer, and a photoinitiator;
the photoinitiator is a hexaaryl-bisimidazole compound; and
the protective layer has a dry coating weight from about 0.5 g/m² to less than about 2.0 g/m², and contains at least one type of poly(vinyl alcohol) having a saponification degree less than about 93 mol %, and a poly(vinyl pyrrolidone) in an amount from 0 to about 10 parts by weight of the poly(vinyl alcohol).

43. The photopolymer printing plate precursor according to claim 42, wherein the protective layer contains a mixture of at least two types of poly(vinyl alcohol) having an overall mean saponification degree of all the polyvinylalcohols of less than about 93 mol-%, and the poly(vinyl pyrrolidone) in an amount from 0 to about 10 parts by weight of all of the polyvinylalcohols.

44. The photopolymer printing plate precursor according to claim 42, wherein the radical stabilizer is a compound selected from the group consisting of phenoles, organic phosphites, organic phosphonites, amines, hydroxylamines, lactones, hydroquinones, divalent sulfur compounds, and metal complexants; wherein the phenoles include mono-, di- and trihydroxyphenyl compounds.

45. The photopolymer printing plate precursor according to claim 43, wherein the radical stabilizer is a compound selected from the group consisting of phenoles, organic phosphites, organic phosphonites, amines, hydroxylamines, lactones, hydroquinones, divalent sulfur compounds, and metal complexants; wherein the phenoles comprise mono-, di- and trihydroxyphenyl compounds.

46. The photopolymer printing plate precursor according to claim 42, wherein the radical stabilizer is a compound selected from the group consisting of hindered phenoles, O-alkylated hydroquinones, organic phosphites, organic phosphonites, aromatic amines, hindered amines, dialkyl hydroxylamines, benzofuranones, and dialkyl thiodipropionates.

47. The photopolymer printing plate precursor according to claim 43, wherein the radical stabilizer is a compound selected from the group consisting of hindered phenoles, O-alkylated hydroquinones, organic phosphites, organic phosphonites, aromatic amines, hindered amines, dialkyl hydroxylamines, benzofuranones, and dialkyl thiodipropionates.

48. The photopolymer printing plate precursor according to claim 42, wherein the sensitizer has a solubility in methyl ethyl ketone of at least about 15 g/kg.

49. The photopolymer printing plate precursor according to claim 43, wherein the sensitizer has a solubility in methyl ethyl ketone of at least about 15 g/kg.

50. The photopolymer printing plate precursor according to claim 44, wherein the sensitizer has a solubility in methyl ethyl ketone of at least about 15 g/kg.

51. The photopolymer printing plate precursor according to claim 45, wherein the sensitizer has a solubility in methyl ethyl ketone of at least about 15 g/kg.

52. The photopolymer printing plate precursor according to claim 46, wherein the sensitizer has a solubility in methyl ethyl ketone of at least about 15 g/kg.

53. The photopolymer printing plate precursor according to claim 47, wherein the sensitizer has a solubility in methyl ethyl ketone of at least about 15 g/kg.

54. The photopolymer printing plate precursor according to claim 48, wherein the sensitizer is an optical brightening agent.

55. The photopolymer printing plate precursor according to claim 49, wherein the sensitizer is an optical brightening agent.

56. The photopolymer printing plate precursor according to claim 50, wherein the sensitizer is an optical brightening agent.

57. The photopolymer printing plate precursor according to claim 51, wherein the sensitizer is an optical brightening agent.

58. The photopolymer printing plate precursor according to claim 52, wherein the sensitizer is an optical brightening agent.

59. The photopolymer printing plate precursor according to claim 53, wherein the sensitizer is an optical brightening agent.

60. The photopolymer printing plate precursor according to claim 58, wherein the binder is a copolymer containing monomeric units of an alpha,beta-unsaturated carboxylic acid and/or an alpha,beta-unsaturated dicarboxylic acid.

61. The photopolymer printing plate precursor according to claim 59, wherein the binder is a copolymer containing monomeric units of an alpha,beta-unsaturated carboxylic acid and/or an alpha,beta-unsaturated dicarboxylic acid.

62. The photopolymer printing plate precursor according to claim 60, wherein the composition further comprises a polyfunctional (meth)acrylate or alkyl(meth)acrylate compound as a crosslinking agent.

63. The photopolymer printing plate precursor according to claim 61, wherein the composition further comprises a polyfunctional (meth)acrylate or alkyl(meth)acrylate compound as a crosslinking agent.

64. The photopolymer printing plate precursor according to claim 62, wherein the polymerizable compound contains a urethane and/or urea group and/or a tertiary amino group.

65. The photopolymer printing plate precursor according to claim 63, wherein the polymerizable compound contains a urethane and/or urea group and/or a tertiary amino group.

66. The photopolymer printing plate precursor according to claim 64, wherein the composition further comprises a radical chain transfer agent.

67. The photopolymer printing plate precursor according to claim 65, wherein the composition further comprises a radical chain transfer agent.

68. The photopolymer printing plate precursor according to claim 66, wherein the radical chain transfer agent is a sulfur containing compound.

69. The photopolymer printing plate precursor according to claim 67, wherein the radical chain transfer agent is a sulfur containing compound.

70. A photopolymer printing plate precursor according to claim 68, wherein the optical brightening agent has a structure according to one of the following formulae: 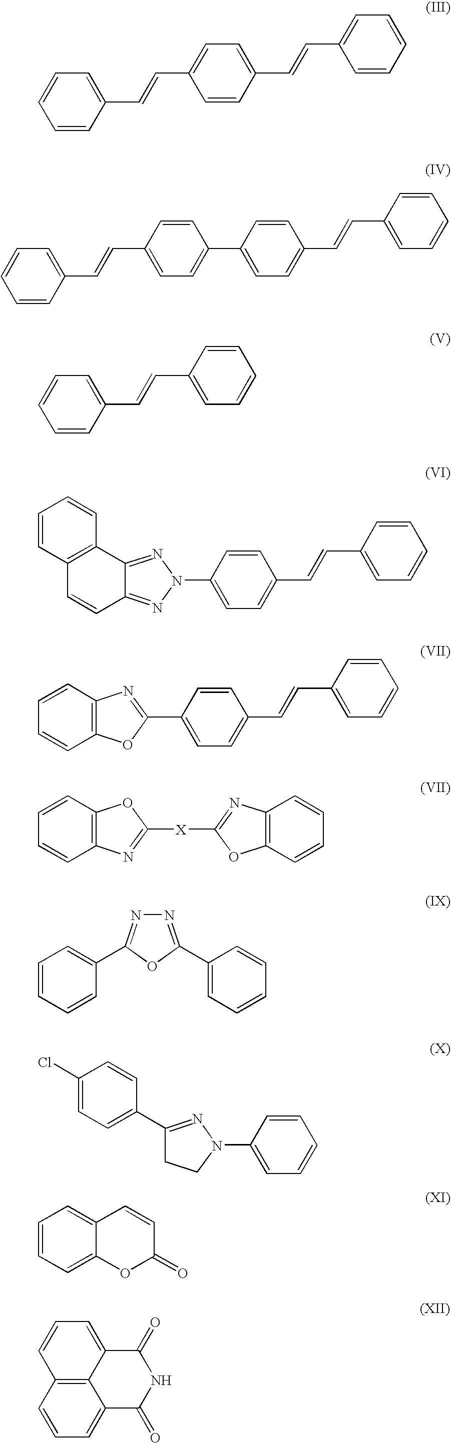 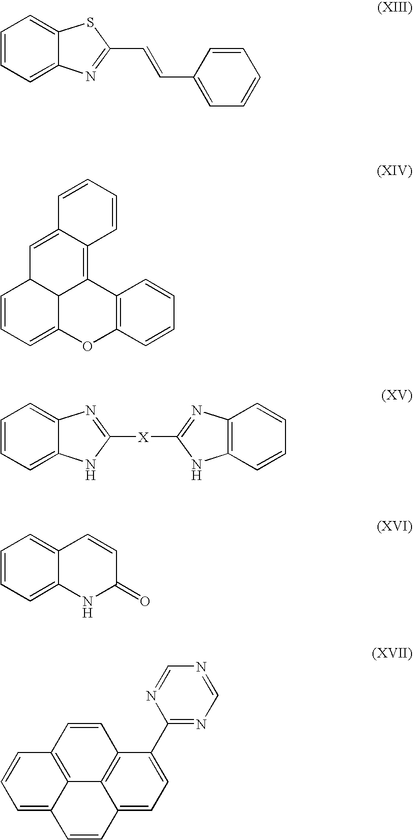
wherein X is one of the following groups, * denoting the position of attachment in the above formulae: 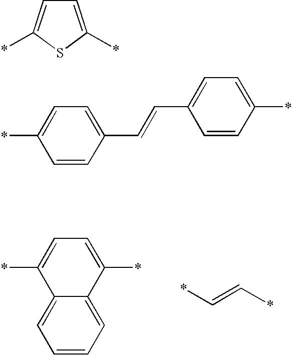
and wherein one or more of the nuclei in each of the above formulae (III) to (XVII) may be independently substituted by one or more groups selected from alkyl, alkoxy, alkylcarbonyl, alkoxycarbonyl, acyloxy, carboxyl, nitrile, amino, hydroxyl, alkylsulfonyl, and aminosulfonyl.

71. A process of making a lithographic printing plate comprising the steps of:
providing the photopolymer printing plate precursor as defined in claim 42;
exposing the printing plate precursor with a laser having an emission wavelength in the range from about 300 nm to about 450 nm;
heating the plate to a temperature, when measured at the back of the plate, from about 90° C. to about 150° C.;
washing off the protective coating; and
processing the printing plate precursor in an aqueous alkaline developer.

72. A process of making a lithographic printing plate comprising the steps of:
providing the photopolymer printing plate precursor as defined in claim 43;
exposing the printing plate precursor with a laser having an emission wavelength in the range from about 300 nm to about 450 nm;
heating the plate to a temperature, when measured at the back of the plate, from about 90° C. to about 150° C.;
washing off the protective coating; and
processing the printing plate precursor in an aqueous alkaline developer.

73. A process of making a lithographic printing plate comprising the steps of:
providing the photopolymer printing plate precursor as defined in claim 44;
exposing the printing plate precursor with a laser having an emission wavelength in the range from about 300 nm to about 450 nm;
heating the plate to a temperature, when measured at the back of the plate, from about 90° C. to about 150° C.;
washing off the protective coating; and
processing the printing plate precursor in an aqueous alkaline developer.

74. A process of making a lithographic printing plate comprising the steps of:
providing the photopolymer printing plate precursor as defined in claim 45;
exposing the printing plate precursor with a laser having an emission wavelength in the range from about 300 nm to about 450 nm;
heating the plate to a temperature, when measured at the back of the plate, from about 90° C. to about 150° C.;
washing off the protective coating; and
processing the printing plate precursor in an aqueous alkaline developer.

75. A process of making a lithographic printing plate comprising the steps of:
providing the photopolymer printing plate precursor as defined in claim 68;
exposing the printing plate precursor with a laser having an emission wavelength in the range from about 300 nm to about 450 nm;
heating the plate to a temperature, when measured at the back of the plate, from about 90° C. to about 150° C.;
washing off the protective coating; and
processing the printing plate precursor in an aqueous alkaline developer.

76. A process of making a lithographic printing plate comprising the steps of:
providing the photopolymer printing plate precursor as defined in claim 69;
exposing the printing plate precursor with a laser having an emission wavelength in the range from about 300 to about 450 nm;
heating the plate to a temperature, when measured at the back of the plate, from about 90° C. to about 150° C.;
washing off the protective coating; and
processing the printing plate precursor in an aqueous alkaline developer.

77. The method according to claim 71, wherein the printing plate precursor is exposed at an energy density, measured on a top surface of the plate, of about 100 μJ/cm² or less.

78. The method according to claim 72, wherein the printing plate precursor is exposed at an energy density, measured on a top surface of the plate, of about 100 μJ/cm² or less.

79. The method according to claim 73, wherein the printing plate precursor is exposed at an energy density, measured on a top surface of the plate, of about 100 μJ/cm² or less.

80. The method according to claim 74, wherein the printing plate precursor is exposed at an energy density, measured on a top surface of the plate, of about 100 μJ/cm² or less.

81. The method according to claim 75, wherein the printing plate precursor is exposed at an energy density, measured on a top surface of the plate, of about 100 μJ/cm² or less.

82. The method according to claim 76, wherein the printing plate precursor is exposed at an energy density, measured on a top surface of the plate, of about 100 μJ/cm² or less.
